(19) United States
(12) Patent Application Publication
(10) Pub. No.: US 2011/0100690 A1
(43) Pub. Date: May 5, 2011

(54) ELECTRICALLY CONDUCTIVE BODY AND PRINTED WIRING BOARD AND METHOD OF MAKING THE SAME

(75) Inventors: Hideaki Yoshimura, Kawasaki (JP); Kenji Fukuzono, Kawasaki (JP); Takashi Kanda, Kawasaki (JP); Tomohisa Yagi, Kawasaki (JP); Hiroki Ikeda, Himeji (JP); Katsu Yanagimoto, Himeji (JP)

(73) Assignees: FUJITSU LIMITED, Kawasaki-shi (JP); SANYO SPECIAL STEEL CO., LTD., Himeji-shi (JP)

(21) Appl. No.: 12/915,786

(22) Filed: Oct. 29, 2010

(30) Foreign Application Priority Data
Oct. 30, 2009 (JP) 2009-250510

(51) Int. Cl. H05K 1/02; B32B 15/08; B23K 35/12; H01B 1/02; B23K 31/02

(52) U.S. Cl. 174/259; 428/457; 228/249; 252/512; 228/165

(57) ABSTRACT

An electrically conductive body includes: a first electrically conductive material; a second electrically conductive material; and a bonding material bonding the first electrically conductive material to the second electrically conductive material at least for electric conduction. The bonding material is made of a metallic structure containing copper-tin based intermetallic compound phases and tin-bismuth phases, the copper-tin based intermetallic compound phases being continuous between the first electrically conductive material and the second electrically conductive material, the tin-bismuth phases being surrounded by the copper-tin based intermetallic compound phases.

### CROSS-REFERENCE TO RELATED APPLICATION

This application is based upon and claims the benefit of priority from the prior Japanese Patent Application No. 2009-250510 filed on Oct. 30, 2009, the entire contents of which are incorporated herein by reference.

### FIELD

The embodiment discussed herein is related to an electrically conductive body and a method of making the same, as well as a printed wiring board and a method of making the same.

### BACKGROUND

Tin powder is well known. The tin powder sometimes comprises tin particles containing the supersaturated solid solution of copper. Quenching process such as atomizing process and melts spanning process is employed to make the supersaturated solid solution of copper. The tin powder melts at 230 degrees Celsius approximately. Solidification induces formation of tin phases and copper-tin alloy phases at the natural ingredient proportion.
[Reference 1] JP Patent Application Publication No. 2008-178909
[Reference 2] JP Patent Application Publication No. 2002-094242
[Reference 3] JP Patent Application Publication No. 2004-234900
[Reference 4] JP Patent Application Publication No. 2001-018090
[Reference 5] JP Patent Application Publication No. 2003-273517
[Reference 6] JP Patent No. 2603053
[Reference 7] JP Patent No. 3034238
[Reference 8] JP Patent No. 3187373
[Reference 9] JP Patent No. 3634984
[Reference 10] JP Patent Application Publication No. 2002-256303
[Reference 11] JP Patent Application Publication No. 2005-340687

Studies are developed to employ the aforementioned tin powder as a so-called solder material. However, insulating materials of a printed wiring board and a package substrate have in general the glass transition temperature in a range between 150 degrees Celsius and 180 degrees Celsius approximately. If solder material has the melting point at a temperature higher than the glass transition temperature, the printed wiring board or the package substrate is subjected to the temperature higher than the glass transition temperature for a long time period. Avoidance of the application of such a high temperature contributes to improvement in reliability of a product.

### SUMMARY

According to an aspect of the invention, an electrically conductive body includes: a first electrically conductive material; a second electrically conductive material; and a bonding material bonding the first electrically conductive material to the second electrically conductive material at least for electric conduction. The bonding material is made of a metallic structure containing copper-tin based intermetallic compound phases and tin-bismuth phases, the copper-tin based intermetallic compound phases being continuous between the first electrically conductive material and the second electrically conductive material, the tin-bismuth phases being surrounded by the copper-tin based intermetallic compound phases.

According to an aspect of the invention, a method of making an electrically conductive body includes: filling up a space between a first electrically conductive material and a second electrically conductive material with electrically conductive paste containing tin powder and tin-bismuth powder, the tin powder comprising tin particles containing a supersaturated solid solution of copper; and heating the electrically conductive paste at a temperature equal to or higher than the eutectic temperature of tin-bismuth alloy and lower than the solidus temperature of copper-tin alloy, thereby forming copper-tin based intermetallic compound phases continuous between the first electrically conductive material and the second electrically conductive material.

According to an aspect of the invention, a printed wiring board includes: a first insulating layer; a first electrically conductive layer formed on the surface of the first insulating layer; an intermediate insulating layer having the back surface overlaid on the first electrically conductive layer, the intermediate insulating layer defining a through bore penetrating through the intermediate insulating layer between the back surface and the front surface opposite to the back surface, a space inside the through bore touching at least partly the surface of the first electrically conductive layer; a second electrically conductive layer overlaid on the intermediate insulating layer, the second electrically conductive layer touching at least partly the space inside the through bore; a second insulating layer overlaid on the second electrically conductive layer; and a bonding material filling up the space inside the through bore, the bonding material bonding the first electrically conductive layer to the second electrically conductive layer at least for electric conduction. The bonding material is made of a metallic structure containing copper-tin based intermetallic compound phases and tin-bismuth phases, the copper-tin based intermetallic compound phases being continuous between the first electrically conductive layer and the second electrically conductive layer, the tin-bismuth phases being surrounded by the copper-tin based intermetallic compound phases.

According to an aspect of the invention, a method of making a printed wiring board includes: forming a space in a second insulating layer overlaid on the surface of a first insulating layer, the space erect on the surface of a first electrically conductive layer formed on the surface of the first insulating layer, the space being open at the surface of the second insulating layer, the space filled up with electrically conductive paste containing tin powder and tin-bismuth powder, the tin powder comprising tin particles containing a supersaturated solid solution of copper; placing the surface of a third insulating layer against the surface of the second insulating layer, thereby closing an opened end of the space with a second electrically conductive layer formed on the surface of the third insulating layer; and heating the electrically conductive paste at a temperature equal to or higher than the eutectic temperature of tin-bismuth alloy and lower than the solidus temperature of copper-tin alloy, thereby forming copper-tin based intermetallic compound phases continuous between the first electrically conductive layer and the second electrically conductive layer.

Electrically conductive paste containing tin powder and tin-bismuth powder, the tin powder comprising tin particles containing a supersaturated solid solution of copper, the electrically conductive paste configured to form copper-tin based intermetallic compound phases continuous at least in a predetermined direction when heated at a temperature equal to or higher than the eutectic temperature of tin-bismuth alloy and lower than the solidus temperature of copper-tin alloy.

The object and advantages of the embodiment will be realized and attained by means of the elements and combinations particularly pointed out in the appended claims. It is to be understood that both the foregoing general description and the following detailed description are exemplary and explanatory and are not restrictive of the embodiment, as claimed.

### BRIEF DESCRIPTION OF THE DRAWINGS

FIG. 1 is a vertical section view schematically illustrating the structure of a printed circuit board unit according to a first embodiment;

FIG. 2 is an enlarged sectional view of a bonding material;

FIG. 3 is a vertical sectional view schematically illustrating an insulating resin sheet used in a method of making a printed wiring board;

FIG. 4 is a vertical sectional view schematically illustrating a first printed wiring board and the insulating resin sheet to be overlaid on the first printed wiring board;

FIG. 5 is a vertical sectional view schematically illustrating a process of boring through bores in the insulating resin sheet on the first printed wiring board;

FIG. 6 is a vertical sectional view schematically illustrating a process of filling the through bores with electrically conductive paste;

FIG. 7 is a vertical sectional view schematically illustrating a process of peeling off a polyethylene terephthalate (PET) film from the surface of the insulating resin sheet;

FIG. 8 is a vertical sectional view schematically illustrating a process of placing the second printed wiring board on the insulating resin sheet on the first printed wiring board;

FIG. 9 is a vertical sectional view schematically illustrating a process of adhering the second printed wiring board to the first printed wiring board;

FIG. 10 is the equilibrium diagram of tin and copper;

FIG. 11 is an electron microscope image depicting the sectional view of tin particles containing the supersaturated solid solution of copper;

FIG. 12 is an electron microscope image depicting the sectional view of tin particles produced without being quenched;

FIG. 13 is a graph depicting the measurement results of the differential scanning calorimetry;

FIG. 14 is a graph depicting the measurement results of the differential scanning calorimetry;

FIG. 15 is a graph depicting the measurement results of the differential scanning calorimetry;

FIG. 16 is a graph depicting the measurement results of the differential scanning calorimetry;

FIG. 17 is the equilibrium diagram of tin and bismuth;

FIG. 18 is a graph depicting the measurement results of the differential scanning calorimetry;

FIG. 19 is a graph depicting the ratio of tin-bismuth eutectic;

FIG. 20 is a graph depicting the measurement results of the differential scanning calorimetry;

FIG. 21 is a graph depicting the measurement results of the differential scanning calorimetry;

FIG. 22 is a graph depicting the measurement results of the differential scanning calorimetry;

FIG. 23 is a graph depicting the measurement results of the differential scanning calorimetry;

FIG. 24 is a graph depicting the measurement results of the differential scanning calorimetry;

FIG. 25 is a vertical sectional view schematically illustrating a process of forming through bores in the insulating resin sheet;

FIG. 26 is a vertical sectional view schematically illustrating a process of supplying the electrically conductive paste onto the surface of the second printed wiring board;

FIG. 27 is a vertical sectional view schematically illustrating a process of placing the second printed wiring board on the first printed wiring board;

FIG. 28 is a vertical sectional view schematically illustrating the insulating resin sheet with a metallic foil attached thereto;

FIG. 29 is a vertical sectional view schematically illustrating a process of forming through bores in the insulating resin sheet with the metallic foil kept on the insulating resin sheet;

FIG. 30 is a vertical sectional view schematically illustrating a process of filling the through bores with the electrically conductive paste;

FIG. 31 is a vertical sectional view schematically illustrating a process of placing the insulating resin sheet holding the electrically conductive paste in the through bores onto the first printed wiring board;

FIG. 32 is a vertical sectional view schematically illustrating a process of solidifying the electrically conductive paste on the surface of the second printed wiring board;

FIG. 33 is a vertical sectional view schematically illustrating a process of placing the second printed wiring board onto the first printed wiring board;

FIG. 34 is a vertical sectional view schematically illustrating the structure of a printed circuit board unit according to a second embodiment;

FIG. 35 is a vertical sectional view schematically illustrating an insulating resin sheet prepared for the production of the printed wiring board;

FIG. 36 is a vertical sectional view schematically illustrating a process of forming through bores and an opening in the insulating resin sheet;

FIG. 37 is a vertical sectional view schematically illustrating a process of placing the insulating resin sheet onto the first printed wiring board;

FIG. 38 is a vertical sectional view schematically illustrating a process of supplying the electrically conductive paste onto the second printed wiring board; and

FIG. 39 is a vertical sectional view schematically illustrating a process of placing the first printed wiring board onto the second printed wiring board.

### DESCRIPTION OF EMBODIMENT

An embodiment of the present invention will be explained below with reference to the accompanying drawings.

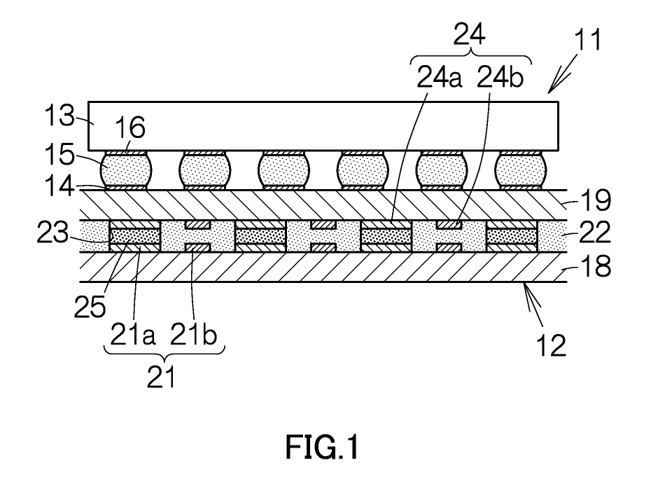

FIG. 1 schematically illustrates a printed circuit board unit according to a first embodiment. The printed circuit board unit 11 includes a printed wiring board 12. A large-scale integrated circuit (LSI) chip 13 as an electronic component is mounted on the printed wiring board 12 serving as an electrically conductive body. A plurality of electrically conductive lands 14 are disposed on the surface of the printed wiring board 12. The electrically conductive lands 14 are configured to receive corresponding solder balls 15, respectively. The solder balls 15 are respectively bonded to the corresponding electrically conductive lands 14 based on metallic diffusion. The solder balls 15 are configured to receive electrically conductive terminals, namely electrically conductive pads 16 of the LSI chip 13. The solder balls 15 are respectively bonded to the corresponding electrically conductive pads 16 based on metallic diffusion. Electric signals are transmitted between the electrically conductive lands 14 and the corresponding electrically conductive pads 16.

The printed wiring board 12 includes a first insulating layer 18 and a second insulating layer 19. The first and second insulating layers 18, 19 have an electrical insulation. The first and second insulating layers 18, 19 are made of thermosetting resin such as epoxy resin, for example. Glass fiber cloth is, for example, embedded in the first and second insulating layers 18, 19. The fibers of the glass fiber cloth extend in the direction along the surface of the first or second insulating layer 18, 19. The glass fiber cloth is impregnated with resin for formation of the first and second insulating layers 18, 19. The glass fiber cloth is made of a woven or nonwoven fabric of glass fiber threads.

A first electrically conductive layer 21 as a first electrically conductive material is formed on the surface of the first insulating layer 18. The first electrically conductive layer 21 includes one or more electrically conductive lands 21a and a wiring pattern 21b. The electrically conductive lands 21a serve as an electrically conductive layer. The electrically conductive lands 21a and the wiring pattern 21b are made from an electrically conductive material such as copper. A noble metal plating film such as a gold plating film, a nickel plating film, or a composite plating film including these films may be formed on the surface of the electrically conductive lands 21a. The wiring pattern 21b connects the electrically conductive lands 21a to one another, for example. The wiring pattern 21b serves to establish various signal paths.

An intermediate insulating layer 22 is overlaid on the surface of the first electrically conductive layer 21. The intermediate insulating layer 22 has an electrical insulation. The intermediate insulating layer 22 is made of thermosetting resin such as epoxy resin, for example. The back surface of the intermediate insulating layer 22 uniformly coheres to the surface of the first insulating layer 18. The intermediate insulating layer 22 covers over the first electrically conductive layer 21. The intermediate insulating layer 22 has one or more through bores 23 penetrating through the intermediate insulating layer 22 from the front surface thereof to the back surface thereof. The individual through bore 23 defines a space touching the corresponding electrically conductive land 21a. The space has a columnar shape having the central axis perpendicular to the flat surface of the electrically conductive land 21a, for example. Alternatively, the intermediate insulating layer 22 may be made of thermoplastic resin such as polyetheretherketone (PEEK), for example.

A second electrically conductive layer 24 as a second electrically conductive material is overlaid on the surface of the intermediate insulating layer 22. The second insulating layer 19 is overlaid on the second electrically conductive layer 24. The back surface of the second insulating layer 19 uniformly coheres to the surface of the second electrically conductive layer 24. The back surface of the second insulating layer 19 simultaneously uniformly coheres to the surface of the intermediate insulating layer 22. The second electrically conductive layer 24 includes one or more electrically conductive lands 24a and a wiring pattern 24b. The electrically conductive lands 24a serve as an electrically conductive layer. The electrically conductive lands 24a and the wiring pattern 24b are made from an electrically conductive material such as copper. A noble metal plating film such as a gold plating film, a nickel plating film, or a composite plating film including these films may be formed on the surface of the electrically conductive lands 24a. The wiring pattern 24b connects the electrically conductive lands 24a to one another, for example. The wiring pattern 24b serves to establish various signal paths.

The individual electrically conductive land 24a of the second electrically conductive layer 24 touch the space inside the corresponding through bore 23. The central axis of the space in the columnar shape is set perpendicular to the flat surface of the electrically conductive land 24a. The space is filled up with an electrically conductive bonding material 25. The bonding material 25 connects the electrically conductive lands 21a of the first electrically conductive layer 21 to the corresponding electrically conductive lands 24a of the second electrically conductive layer 24, respectively, for electric conduction. So-called vias are thus formed. Electric connection is established. Electric signals are transmitted between the electrically conductive lands 21a and the corresponding electrically conductive lands 24a. Various signal paths are in this manner established on the printed wiring board 12. Electric signals are transmitted between the LSI chip 13 and other electronic component or components on the printed wiring board 12.

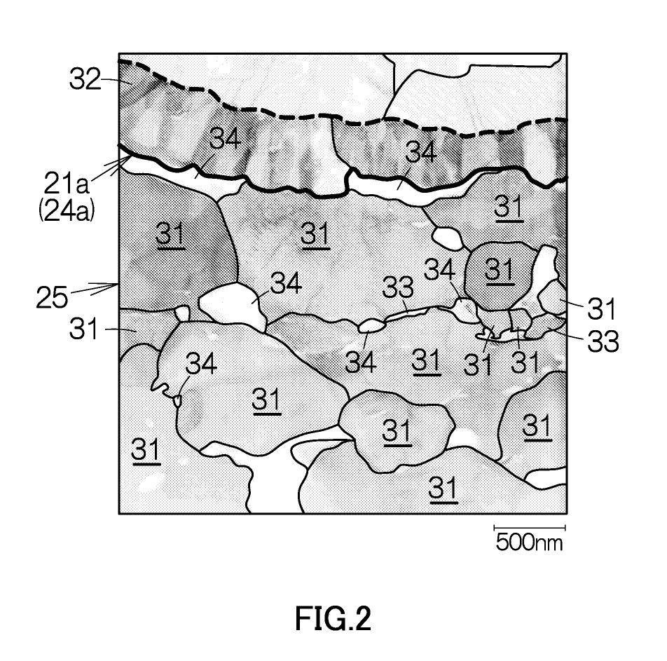

FIG. 2 illustrates an enlarged sectional view of the boding material 25. The bonding material 25 is made of a metallic structure containing copper-tin based intermetallic compound phases 31. The individual copper-tin based intermetallic compound phases 31 is made of Cu₆Sn₅. The adjacent copper-tin based intermetallic compound phases 31 cohere to one another. The copper-tin based intermetallic compound phases 31 is continuous from the electrically conductive land 21a of the first electrically conductive layer 21 to the corresponding electrically conductive land 24a of the second electrically conductive layer 24. The continuous arrangement of the copper-tin based intermetallic compound phases 31 provides an electrical current path having electrical conductivity.

A diffusion layer 32 is formed on the surfaces of the electrically conductive lands 21a, 24a. The diffusion layer 32 is made of Cu₃Sn. Tin included in the bonding material 25 diffuses into the electrically conductive lands 21a, 24a to establish the diffusion layer 32. The diffusion layer 32 serves to bond the copper-tin based intermetallic compound phases 31 to the electrically conductive lands 21a, 24a. The copper-tin based intermetallic compound phases 31 in this manner form the signal path between the electrically conductive lands 21a and the corresponding electrically conductive lands 24a.

The bonding material 25 further contains tin-bismuth materials 33 and matrix resin materials 34. The tin-bismuth materials 33 are made of a binary alloy of tin-bismuth. The matrix resin materials 34 are made of a thermosetting resin material such as epoxy resin, for example. The tin-bismuth materials 33 are contained in the bonding material 25 at the content enough to avoid melting reaction of the bonding material 25 at a temperature lower than a temperature related to the eutectic temperature intrinsic to the tin-bismuth alloy, namely at a temperature lower than 139 degrees Celsius approximately. The tin-bismuth materials 33 exist in patches between the adjacent copper-tin based intermetallic compound phases 31 as well as between the copper-tin based intermetallic compound phases 31 and the electrically conductive lands 21a, 24a. Since the tin-bismuth materials 33 are in this manner separated from one another by the copper-tin based intermetallic compound phases 31 in a fragmented manner, the melting reaction of the tin-bismuth materials 33 is closely packed within gaps between the adjacent copper-tin based intermetallic compound phases 31. Accordingly, the bonding material 25 is prevented from melting reaction at a temperature lower than a temperature related to the eutectic temperature intrinsic to the tin-bismuth alloy. The melting point of the bonding material 25 can be raised up to the melting point of Cu₆Sn₅, namely 415 degrees Celsius approximately. The bonding material 25 is thus prevented from melting in a range up to a relatively high temperature. The bonding material 25 is kept in the solid phase in a range up to a relatively high temperature. The bonding material 25 is given an improved heat resistance. Even when the printed wiring board 12 is repeatedly subjected to heating process because of replacement of the LSI chip 13, etc., the electrical conductivity of the bonding material 25 is reliably kept in a good condition. The matrix resin materials 34 likewise exist in patches between the adjacent copper-tin based intermetallic compound phases 31 as well as between the copper-tin based intermetallic compound phases 31 and the electrically conductive lands 21a, 24a.

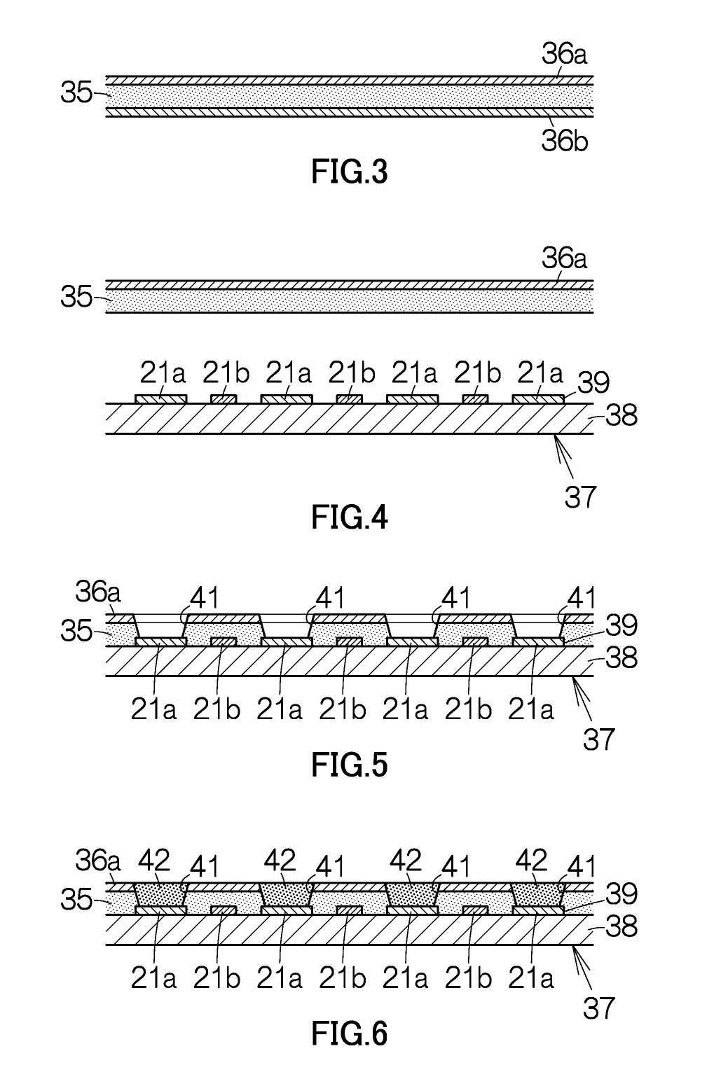

Next, description will be made on a method of making the printed wiring board 12 according to a first example. First of all, an insulating resin sheet 35 as a second insulating layer is prepared, as depicted in FIG. 3. The insulating resin sheet 35 is made of thermosetting resin such as epoxy resin, for example. Alternatively, the insulating resin sheet 35 may be made of thermoplastic resin such as polyetheretherketone (PEEK), for example. A general prepreg may be utilized for the insulating resin sheet 35. Polyethylene terephthalate (PET) films 36a, 36b are adhered to the respective front and back surfaces of the insulating resin sheet 35.

As depicted in FIG. 4, a first printed wiring board 37 is prepared. The first printed wiring board 37 includes an insulating layer 38 and an electrically conductive layer 39. The insulating layer 38 corresponds to the aforementioned first insulating layer 18. The electrically conductive layer 39 corresponds to the aforementioned first electrically conductive layer 21. The electrically conductive layer 39 is formed on the surface of the insulating layer 38. A copper foil is, for example, cohered to the surface of the insulating layer 38 so as to form the electrically conductive layer 39. Photolithography technique is, for example, employed to form or shape the electrically conductive lands 21a and the wiring pattern 21b out of the copper foil.

The insulating resin sheet 35 is overlaid on the surface of the first printed wiring board 37. A PET film 36b is peeled off from the back surface of the insulating resin sheet 35. The back surface of the insulating resin sheet 35 is received on the surface of the first printed wiring board 37. The back surface of the insulating resin sheet 35 is forced to cohere to the surface of the insulating layer 38. The insulating resin sheet 35 covers over the electrically conductive lands 21a and the wiring pattern 21b.

As depicted in FIG. 5, through bores 41 are formed in the insulating resin sheet 35 at positions corresponding to the individual electrically conductive lands 21a. The through bores 41 penetrate through the insulating resin sheet 35. The individual through bore 41 defines a space erect on the flat surface of the corresponding electrically conductive land 21a. The through bores 41 are open at the surface of the insulating resin sheet 35. The through bores 41 simultaneously penetrate through the PET film 36a. Carbon dioxide gas (CO₂ gas) laser is utilized to bore the through bores 41, for example. The through bores 41 are formed in response to the sublimation of the insulating resin sheet 35 and the PET film 36a. The individual through bore 41 defines a columnar space or an upside-down truncated-cone shaped space. The central axis of the columnar space or upside-down truncated-cone shaped space is set perpendicular to the flat surface of the electrically conductive land 21a at the center of the electrically conductive land 21a. At least the diameter of the lower end of the through bore 41 is set smaller than the diameter of the electrically conductive land 21a. Accordingly, the insulating layer 38 is reliably prevented from suffering from damages resulting from the irradiation of the CO₂ gas laser during the formation of the through bores 41. Additionally, plasma treatment may be effected on the surface of the electrically conductive lands 21a inside the through bores 41 after the through bores 41 have been formed. The plasma treatment serves to remove residue of resin remaining on the interfaces of the electrically conductive lands 21a after the through bores 41 have been formed.

As depicted in FIG. 6, the space inside the through bores 41 is filled up with electrically conductive paste 42. The electrically conductive paste 42 is printed on the surface of the PET film 36a. The PET film 36a is allowed to serve as a stencil sheet. Alternatively, a metal mask may be employed as a stencil plate in place of the PET film 36a. In this case, openings may be formed in the metal mask at positions corresponding to the through bores 41. The metal mask contributes to an increased amount of the electrically conductive paste 42 supplied into the individual through bores 41. Otherwise, a dispenser may be utilized to supply the electrically conductive paste 42. A method of supplying the electrically conductive paste 42 is not limited to those mentioned method.

The electrically conductive paste 42 contains tin powder comprising tin particles, tin-bismuth powder and a resin binder. The individual tin particle contains the solid solution of copper supersaturated into the individual tin particles. The resin binder is made of a thermosetting resin material such as epoxy resin, for example. The electrically conductive paste 42 is configured to have the melting point at a temperature equal to or lower than 170 degrees Celsius approximately. The electrically conductive paste 42 will later be described in detail.

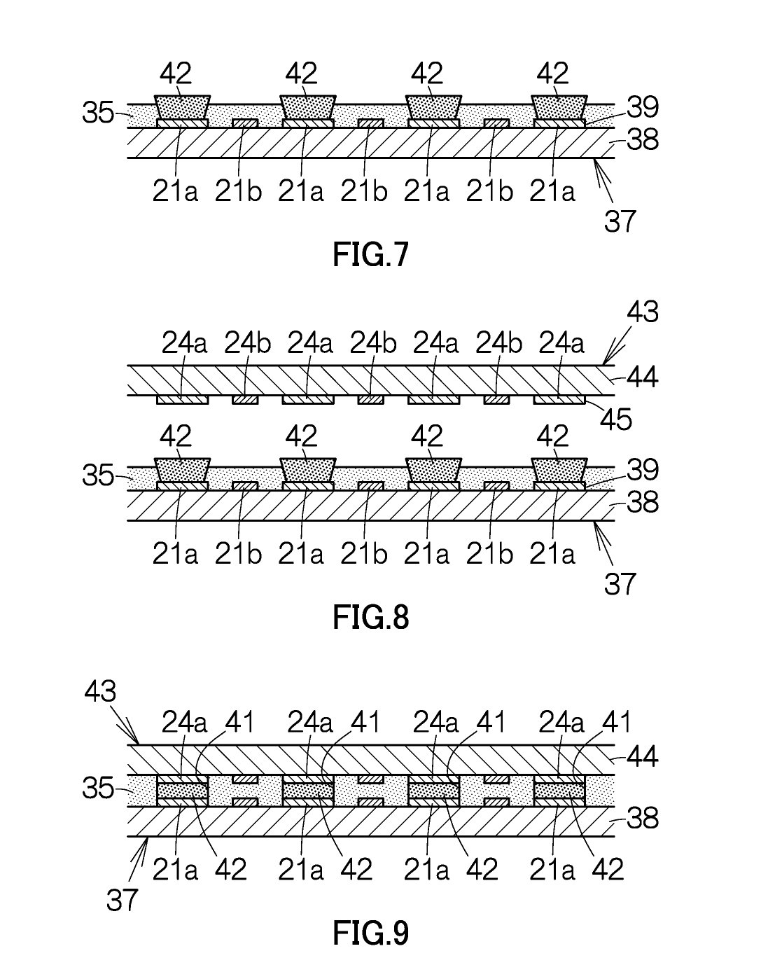

As depicted in FIG. 7, the PET film 36a is thereafter removed from the surface of the insulating resin sheet 35. The surface of the insulating resin sheet 35 gets exposed. The electrically conductive paste 42 that has filled up the through bores 41 inside the PET film 36a remains as it stands. The electrically conductive paste 42 swells from the opened end of the individual through bore 41 by the height corresponding to the thickness of the PET film 36a. The viscosity and/or the thixotropy of the electrically conductive paste 42 and/or the diameter of the through bores 41 are adjusted or optimized to establish the swell of the electrically conductive paste 42. The level of the opened end of the through bore 41 can be adjusted through adjustment of the thickness of the PET film 36a.

As depicted in FIG. 8, a second printed wiring board 43 is overlaid on the first printed wiring board 37 after the through bores 41 have been filled up with the electrically conductive paste 42. The second printed wiring board 43 includes an insulating layer 44 and an electrically conductive layer 45. The insulating layer 44 corresponds to the aforementioned second insulating layer 19. The electrically conductive layer 45 corresponds to the aforementioned second electrically conductive layer 24. The electrically conductive layer 45 is formed on the surface of the insulating layer 44. A copper foil is, for example, cohered to the surface of the insulating layer 44 so as to form the electrically conductive layer 45. Photolithography technique is, for example, employed to form or shape the electrically conductive lands 24a and the wiring pattern 24b out of the copper foil. The reversed second printed wiring pattern 43 is then received on the surface of the surface of the first printed wiring board 37.

As depicted in FIG. 9, the front surface of the second printed wiring board 43 is placed on the surface of the insulating resin sheet 35. The front surface of the insulating layer 44 is forced to cohere to the surface of the insulating resin sheet 35. The opened end of the individual through bore 41 is closed with the corresponding electrically conductive land 24a. Since the electrically conductive paste 42 swells from the opened end of the corresponding through bore 41 in the aforementioned manner, the individual through bore 41 is reliably filled up with the electrically conductive paste 42 when the second printed wiring board 43 is urged against the first printed wiring board 37. The electrically conductive lands 24a are thus allowed to reliably touch the electrically conductive paste 42.

While the second printed wiring board 43 is kept urged against the first printed wiring board 37, the first and second printed wiring boards 37, 43 are subjected to heat treatment. The heat treatment is conducted in the vacuum environment. The heating temperature is, for example, set at 170 degrees Celsius approximately. The insulating resin sheet 35 gets softened. Accordingly, the insulating resin sheet 35 deforms to fit the inequality of the surfaces of the first and second printed wiring boards 37, 43 in response to the application of the pressure or urging force. The swell of the electrically conductive lands 21a, 24a and the wiring patterns 21b, 24b as well as the inequality of the insulating layers 38, 44 are fully received in the insulating resin sheet 35. Clearance or voids are completely eliminated between the surface of the first printed wiring board 37 and the insulating resin sheet 35. The insulating resin sheet 35 is uniformly brought into tight contact with the surface of the first printed wiring board 37. Clearance and voids are likewise completely eliminated between the surface of the second printed wiring board 43 and the insulating resin sheet 35. The insulating resin sheet 35 is uniformly brought into tight contact with the surface of the second printed wiring board 43.

When the temperature exceeds the eutectic temperature of the tin-bismuth alloy, the tin-bismuth powder melts in the electrically conductive paste 42. The melt of the tin-bismuth powder induces the melt of the tin particles. Tin and copper are integrated into a mass. Tin and copper form the copper-tin based intermetallic compound, namely Cu₆Sn₅, in accordance with the ratio of phases derived from the equilibrium diagram of tin and copper. Tin diffuses into the electrically conductive lands 21a, 24a. The diffusion layers 32 made of the copper-tin based intermetallic compound, namely Cu₆Sn₅, is formed in the electrically conductive lands 21a, 24a. Parallel application of heat and pressure in the aforementioned manner causes the remaining liquid of the tin-bismuth to protrude into the surrounding portion of a low pressure. The metallic structure made of the copper-tin based intermetallic compound phases 31 fully occupies the space inside the through bores 41. The electrically conductive paste 42 in this manner provides the bonding material 25.

The insulating resin sheet 35 and the resin binder in the electrically conductive paste 42 then get hardened. The insulating resin sheet 35 corresponds to the intermediate insulating layer 22. The resin binder corresponds to the matrix resin materials 34. The solidified tin-bismuth after being cooled corresponds to the tin-bismuth materials 33. The through bores 41 function as electrically conductive vias.

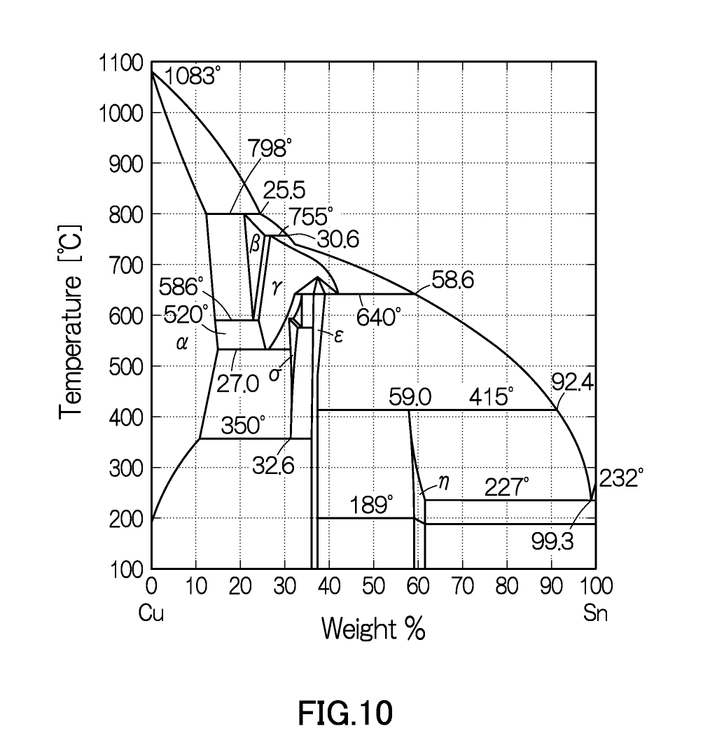

Here, description will be made on a method of making the electrically conductive paste 42. First of all, tin powder is prepared. The tin powder is made of tin particles containing the solid solution of copper supersaturated into the tin particles. Gas atomizing process as an example of quenching process is employed to produce the tin powder. Specimen is prepared to conduct the gas atomizing process. Tin in the amount equal to 75 weight % to the entire specimen is mixed with copper in the amount equal to 25 weight % to the entire specimen to form the entire specimen. The particles having the size equal to or smaller than 10 μm are classified out of the produced alloy powder. The employment of the quenching process enables generation of the forcedly supersaturated solid solution of copper in the tin particles in place of the natural generation of the intermetallic compounds of Cu₆Sn₅. The intermetallic compounds are thus observed in an amount greatly smaller than the theoretical amount calculated based on the ratio between tin and copper. As depicted in FIG. 10 illustrating the equilibrium diagram of tin and copper, the melting point of the tin particles, namely of the copper-tin alloy can thus be set at 227 degrees Celsius.

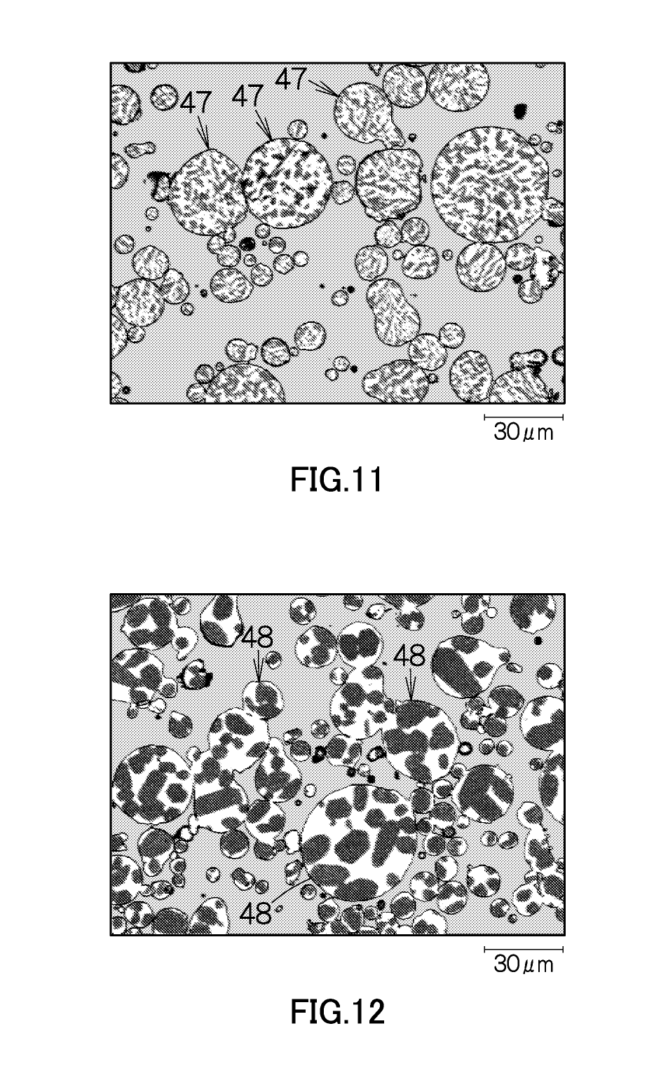

The inventors observed the cross-section of the tin particles produced through the quenching process in the aforementioned manner. An electron microscope was employed to observe the tin particles. As depicted in FIG. 11, the inventors observed the fine submicron islands of the intermetallic compounds of Cu₆Sn₅ dispersed in the copper-tin alloy phases in the tin particles 47 containing the supersaturated solid solution of copper. White or light-colored portions correspond to the copper-tin phases in the tin particles 47 in FIG. 11. Dark-colored portions dispersed in the white portions correspond to the intermetallic compounds. As depicted in FIG. 12, bulks of intermetallic compounds of Cu₆Sn₅ are observed continuous in the tin phases in tin particles 48 produced without being quenched. White or light-colored portions correspond to the tin phases in the tin particles 48 in FIG. 12. Dark-colored portions dispersed in the white portions correspond to the intermetallic compounds.

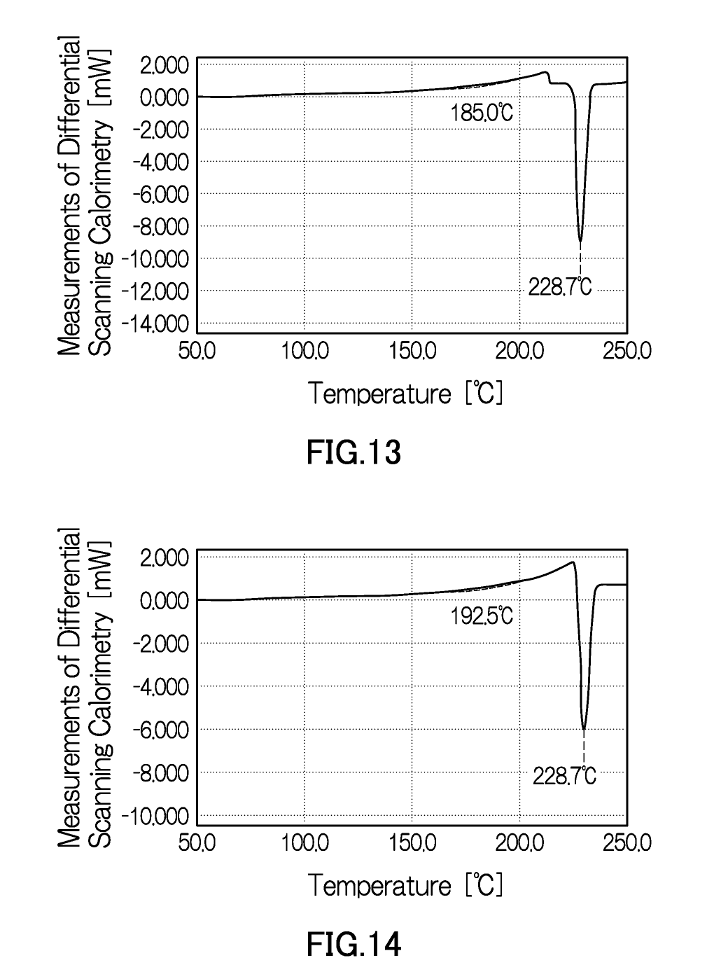

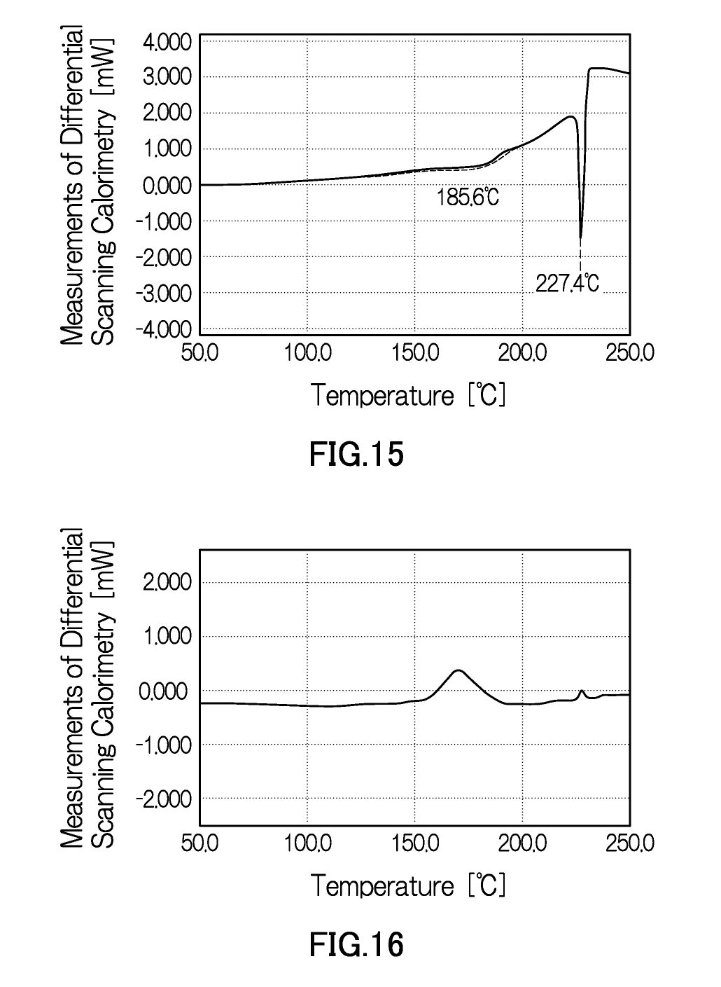

The inventors observed the melting point of the tin particles produced through the quenching process in the aforementioned manner. Differential scanning calorimetry (DSC) was conducted. First, the inventors prepared a specimen resulting from the mixture of tin in the amount of 85 weight % and copper in the amount of 15 weight % for the gas atomizing process. As depicted in FIG. 13, the tin particle containing the supersaturated solid solution of copper showed the peak of the endothermic reaction at 228.7 degrees Celsius. The melting reaction was observed in the vicinity of 227 degrees Celsius. The inventors likewise prepared a specimen resulting from the mixture of tin in the amount of 75 weight % and copper in the amount of 25 weight % for the gas atomizing process. As depicted in FIG. 14, the tin particle containing the supersaturated solid solution of copper showed the peak of the endothermic reaction at 228.7 degrees Celsius. The melting reaction was observed in the vicinity of 227 degrees Celsius. The inventors likewise prepared a specimen resulting from the mixture of tin in the amount of 68 weight % and copper in the amount of 32 weight % for the gas atomizing process. As depicted in FIG. 15, the tin particle containing the supersaturated solid solution of copper showed the peak of the endothermic reaction at 227.4 degrees Celsius. The melting reaction was observed in the vicinity of 227 degrees Celsius. The inventors likewise prepared a specimen resulting from the mixture of tin in the amount of 40 weight % and copper in the amount of 60 weight % for the gas atomizing process. As depicted in FIG. 16, the inventors did not observe the endothermic reaction. The exothermic reaction was observed in the vicinity of 170 degrees Celsius. Crystallization of copper-tin alloy was observed. Accordingly, the tin powder containing the supersaturated solid solution of copper preferably includes the tin ingredient and the copper ingredient at the proportion to set the eutectic temperature of copper-tin alloy at 227 degrees Celsius in the aforementioned electrically conducive paste 42. If the eutectic temperature of the copper-tin alloy exceeds 227 degrees Celsius in response to an increased copper ingredient, the melting point of the electrically conductive paste 42 rises. A rise in the melting point is not preferable.

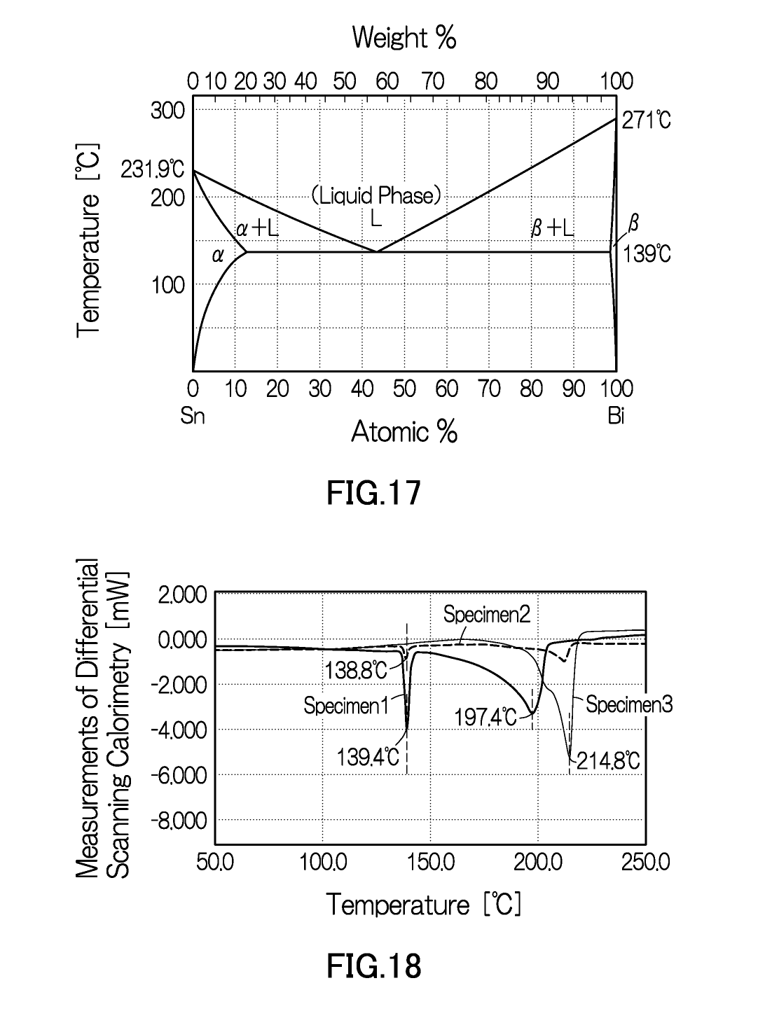

The tin-bismuth powder is mixed with the aforementioned tin particles to produce the electrically conductive paste 42. The tin-bismuth powder is produced for the mixture. The tin-bismuth powder is made of tin-bismuth eutectic alloy. Specifically, the alloy contains tin in the amount of 42 weight % and bismuth in the amount of 58 weight % in the tin-bismuth powder. The particles having the size equal to or smaller than 10 μm are classified out of the produced tin-bismuth alloy powder. The mixture of the tin-bismuth powder serves to lower the melting point (liquidus temperature) of the electrically conductive paste 42. The electrically conductive paste 42 is preferably allowed to melt in a range lower than the heat-resistance temperatures, namely the glass transition temperatures of the insulating resin sheet 35 and the insulating layer 44. Accordingly, the melting point of the tin-bismuth powder is set in a range lower than the glass transition temperatures of the insulating layer 38, the insulating resin sheet 35 and the insulating layer 44. As is apparent from FIG. 17 illustrating the equilibrium diagram of tin-bismuth, for example, the proportion is adjusted between tin ingredient and bismuth ingredient so as to set the melting point at a desired temperature. For example, when the insulating layers 38, 44 and the insulating resin sheet 35 have the glass transition temperature equal to 170 degrees Celsius, the tin-bismuth powder may contain tin in the amount in a range from 30 weight % to 70 weight % to the entire tin-bismuth powder.

The proportion is adjusted between the tin powder and the tin-bismuth powder so as to produce the copper-tin based intermetallic compound phases. The tin-bismuth powder in the amount equal to or smaller than 15 weight % to the total amount of the tin powder and the tin-bismuth powder is mixed in the case where the ratio of tin in the amount of 75 weight % and copper in the amount of 25 weight % is established in the tin particles containing the supersaturated solid solution of copper. The powder resulting from the mixture of this proportion melts at a temperature equal to or higher than the melting point of the tin-bismuth powder and lower than the melting point of the tin powder. Specifically, the melting point of the powder resulting from the mixture is set in a range lower than the glass transition temperatures of the insulating layer 38, the insulating resin sheet 35 and the insulating layer 44. In addition, when the powder resulting from the mixture gets solidified after being melted, it is possible to avoid the melting reaction of the solidified material at a temperature equal to or lower than a temperature related to the eutectic temperature intrinsic to tin-bismuth, namely equal to or lower than 139 degrees Celsius approximately. Here, as is apparent from FIG. 17, the mixture of bismuth in the tin-bismuth alloy in a range from 20 weight % to 99 weight % enables consistency between the solidus temperature of the tin-bismuth and the eutectic temperature of the tin-bismuth.

The inventors conducted the differential scanning calorimetry on the solidified material resulting from the mixture of tin powder, made of tin particles containing the supersaturated solid solution of copper, and tin-bismuth powder. The ratio of tin in the amount of 75 weight % and copper in the amount of 25 weight % was established in the entire tin powder made of the tin particles. The ratio of tin in the amount of 42 weight % and the bismuth in the amount of 58 weight % was established in the entire tin-bismuth powder. Activator was added to the mixture of powder for the melting reaction of the mixture of powder. The mixture of powder melted with the application of heat. After the mixture of powder has gotten solidified, the differential scanning calorimetry was conducted on the mixture of powder in the re-melted state. The tin powder in the amount of 70 weight % was mixed with the tin-bismuth powder in the amount of 30 weight % so as to form the 100 weight % entire mixed powder of the specimen 1. As depicted in FIG. 18, the endothermic reaction, namely the melting reaction, was observed for the mixture material according to the specimen 1. The tin powder in the amount of 80 weight % was mixed with the tin-bismuth powder in the amount of 20 weight % so as to form the 100 weight % entire mixed powder of the specimen 2. As depicted in FIG. 18, a slight endothermic reaction, namely a slight melting reaction, was observed for the mixture material according to the specimen 2. The endothermic reaction of the specimen 2 was so weaker than the endothermic reaction of the specimen 1. The tin powder in the amount of 90 weight % was mixed with the tin-bismuth powder in the amount of 10 weight % so as to form the 100 weight % entire mixed powder of the specimen 3. As depicted in FIG. 18, the endothermic reaction disappeared for the mixture material according to the specimen 3. In other words, the melting reaction of the mixture material was avoided in a range equal to or lower than the eutectic temperature intrinsic to tin-bismuth alloy in the mixture material according to the specimen 3.

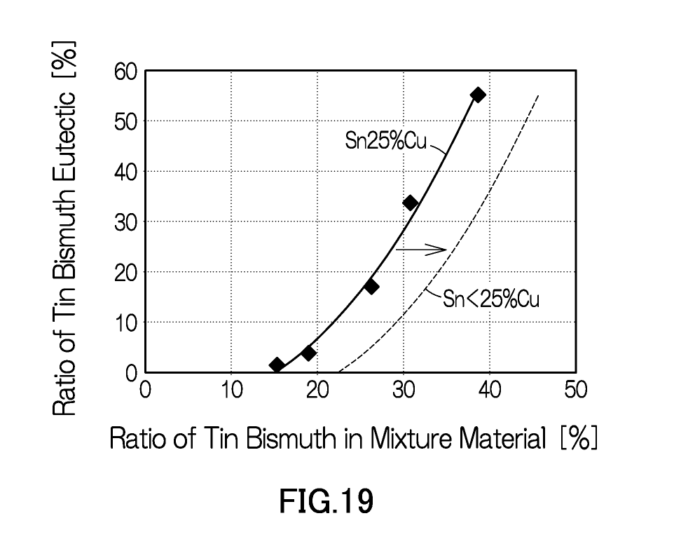

Furthermore, the inventors calculated the ratio of tin-bismuth eutectic remaining in the mixture material. A solidified material was formed based on the mixed powder of tin powder, made of tin particles containing the supersaturated solid solution of copper, and tin-bismuth powder. The ratio of tin in the amount of 75 weight % and copper in the amount of 25 weight % was established in the entire tin powder made of the tin particles in the aforementioned manner. The ratio of tin in the amount of 42 weight % and the bismuth in the amount of 58 weight % was established in the entire tin-bismuth powder. Activator was added to the mixture of powder for the melting reaction of the mixture of powder. The mixture of powder melted with the application of heat. After the mixture of powder has gotten solidified, the ratio or content of the remaining tin-bismuth eutectic was calculated. The tin-bismuth powder was mixed in the mixture of powder at various proportions. As depicted in FIG. 19, when the proportion of tin-bismuth powder falls below 15 weight %, it has been confirmed that the tin-bismuth eutectic disappeared. In other words, if the proportion of the tin-bismuth powder is set below 15 weight % in the mixture of powder, the endothermic reaction is supposed to disappear in the solidified mixture material. Here, the inventors confirmed that the curve moves rightward in FIG. 19 when the content of copper reduces or decreases in the tin powder. Specifically, the endothermic reaction is supposed to disappear in the solidified mixture material, when the proportion of the tin-bismuth powder is set below 15 weight % in the mixture of powder, even if the content of copper is set equal to or smaller than 25 weight % in the tin powder.

A viscous agent is mixed to the mixture of tin powder and the tin-bismuth powder for the production of the electrically conductive paste 42. The viscous agent serves to establish the paste state of the mixture powder. The viscous agent is, for example, made of epoxy resin (bisphenol A type and bisphenol F type) in the amount of 100 weight parts, a hardener namely methyltetrahydrophthalic anhydride in the amount of 73 weight parts, organic acid namely adipic acid in the amount of 20 weight parts, and thixotropy accelerator namely stearic acid amide in the amount of 10.3 weight parts. Here, the organic acid functions as activator. The viscous agent is added in the amount of 14.5 weight % in the entire 100 weight % electrically conductive paste 42. Alternatively, the combination of a specific thermosetting resin, a hardener, an organic acid and a hardening catalyst may be employed as a viscous agent. In this case, bisphenol A epoxy resin, bisphenol B epoxy resin, bisphenol F epoxy resin, naphthalene epoxy resin, brominated epoxy resin, phenol novolac epoxy resin, cresol novolac epoxy resin, biphenyl epoxy resin, alicyclic epoxy resin, acrylic resin, urethane resin and unsaturated polyester resin, for example, may be employed as the thermosetting resin. The hardener may include, for example, acid anhydride such as nnethyltetrahydrophthalic anhydride, methyl hexahydrophthal ic anhydride, methylhimic anhydride, hexahydrophthalic anhydride, trialkyltetrahydrophthalic anhydride, tetrahydrophthalic anhydride, methylcyclohexenedicarboxylic acid, and nadic anhydride, in addition to an amine based hardener such as diethylenetriamine, triethylenetetramine, menthen diamine, isophorone diamine, metaxilene diamine, diaminodiphenylmethane, metaphenylene diamine, and diaminodiphenylsulfone, as well as a phenol hardener such as phenol novolac system, paraxylylene denatured phenol system and dicyclopentadiene denatured phenol system. The organic acid may include, for example, succinic anhydride, maleic anhydride, benzoic anhydride, phthalic anhydride, citraconic anhydride, hexanoic anhydride, glycolic anhydride, glutaric anhydride, succinic acid, sebacic acid, adipic acid, L-glutamic acid, glutaric acid, stearic acid, palmitic acid and abietic acid. The hardening catalyst may include, for example, the imidazole class, the organic phosphine class, diazabicycloundecene, diazabicycloundecene toluenesulfonic acid salt and diazabicycloundecene tolueneoctyric acid salt. It should be noted that the hardening catalyst is used in parallel with the organic acid of the carboxylic acid even though the carboxylic acid added as the activator also functions as the hardening catalyst.

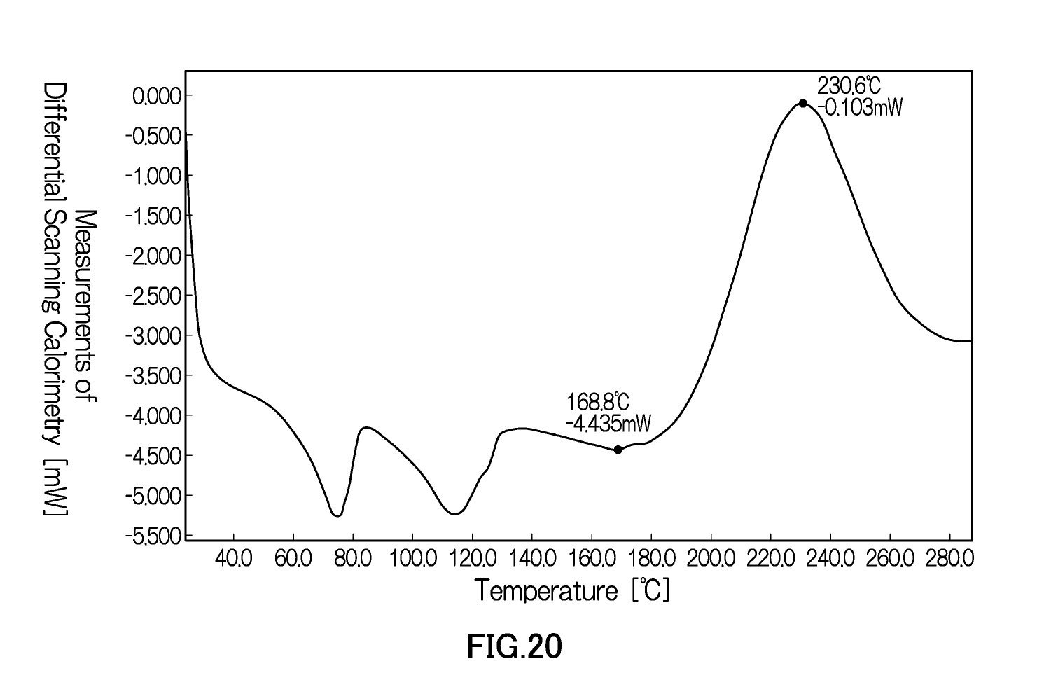

Furthermore, the inventors observed the hardening reaction of the acid anhydride hardener. The inventors prepared the epoxy resin adhesive for the observation. The inventor mixed epoxy resin made of bisphenol A epoxy resin in the amount of 7.4 weight % and bisphenol F epoxy resin in the amount of 41.9 weight %, a hardener made of methyltetrahydrophthalic anhydride in the amount of 36.0 weight %, an activator made of adipic acid in the amount of 9.8 weight %, and thixotropy accelerator made of stearic acid amide in the amount of 4.9 weight %. No reaction catalyst such as imidazole amine based catalyst was added. Differential scanning calorimetry was conducted for the resin adhesive. The temperature was raised by 10 degrees per one minute during the measurement. As depicted in FIG. 20, the peak of the exothermicity was observed at the 230.6 degrees Celsius. The temperature of 230.6 degrees Celsius was determined as the hardening reaction temperature.

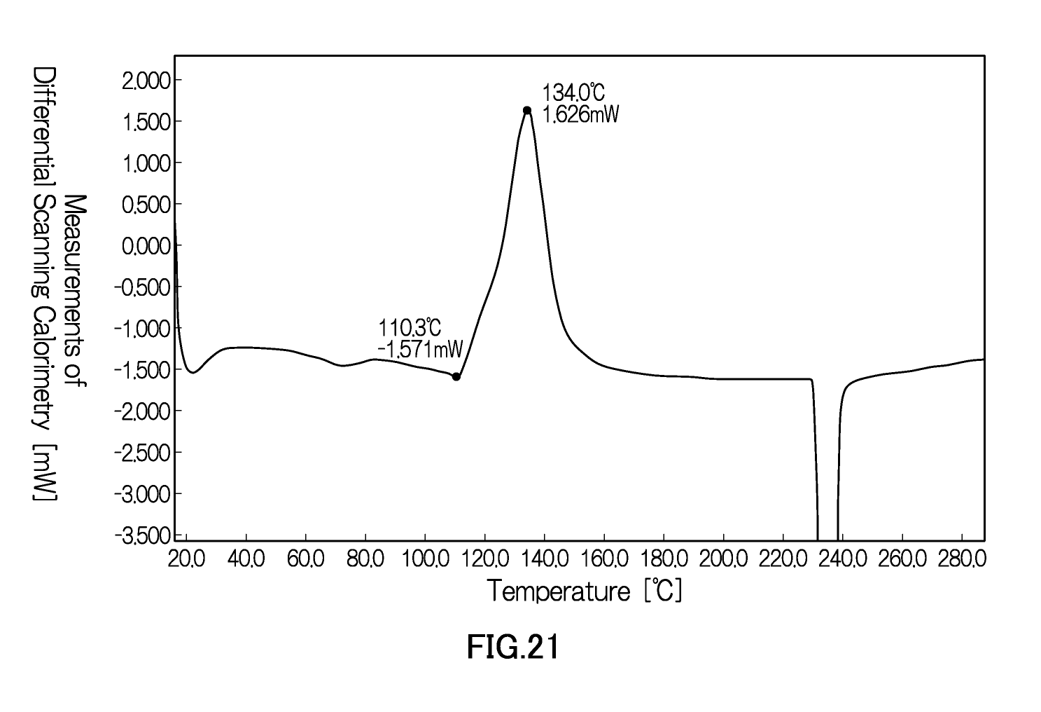

The inventors mixed the prepared epoxy resin adhesive with the tin powder. The proportion was set to have the epoxy resin adhesive in the amount of 15.5 weight % and the tin powder in the amount of 84.5 weight %. The diameter of the particles was set equal to or smaller than 38 μm in the tin powder. No reaction catalyst was added. The mixture was then subjected to measurement of the differential scanning calorimetry. The temperature was raised by 10 degrees per one minute during the measurement. As depicted in FIG. 21, the peak of the exothermicity was observed at the 134.0 degrees Celsius. The temperature of 134.0 degrees Celsius was determined as the hardening reaction temperature. It has been confirmed that the hardening reaction temperature drops in response to the addition of the tin powder.

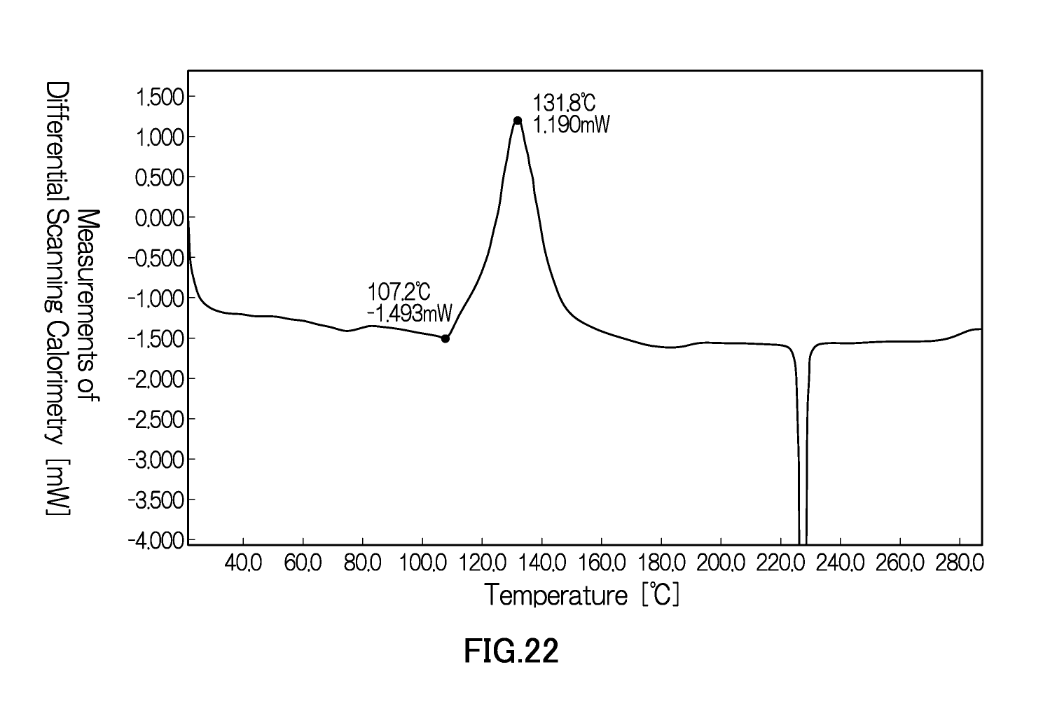

The inventors mixed the aforementioned prepared epoxy resin adhesive with the copper-tin powder. The proportion was set to have the epoxy resin adhesive in the amount of 15.5 weight % and the copper-tin powder in the amount of 84.5 weight %. The proportion was set to have copper in the amount of 25 weight % and tin in the amount of 75 weight % in the copper-tin alloy in the copper-tin powder. The diameter of the particles was set equal to or smaller than 10 μm (the average diameter of 3.0 μm approximately) in the copper-tin powder. No reaction catalyst was added. The mixture was then subjected to measurement of the differential scanning calorimetry. The temperature was raised by 10 degrees per one minute during the measurement. As depicted in FIG. 22, the peak of the exothermicity was observed at the 131.8 degrees Celsius. The temperature of 131.8 degrees Celsius was determined as the hardening reaction temperature. It has been confirmed that the hardening reaction temperature drops in response to the addition of the copper-tin powder.

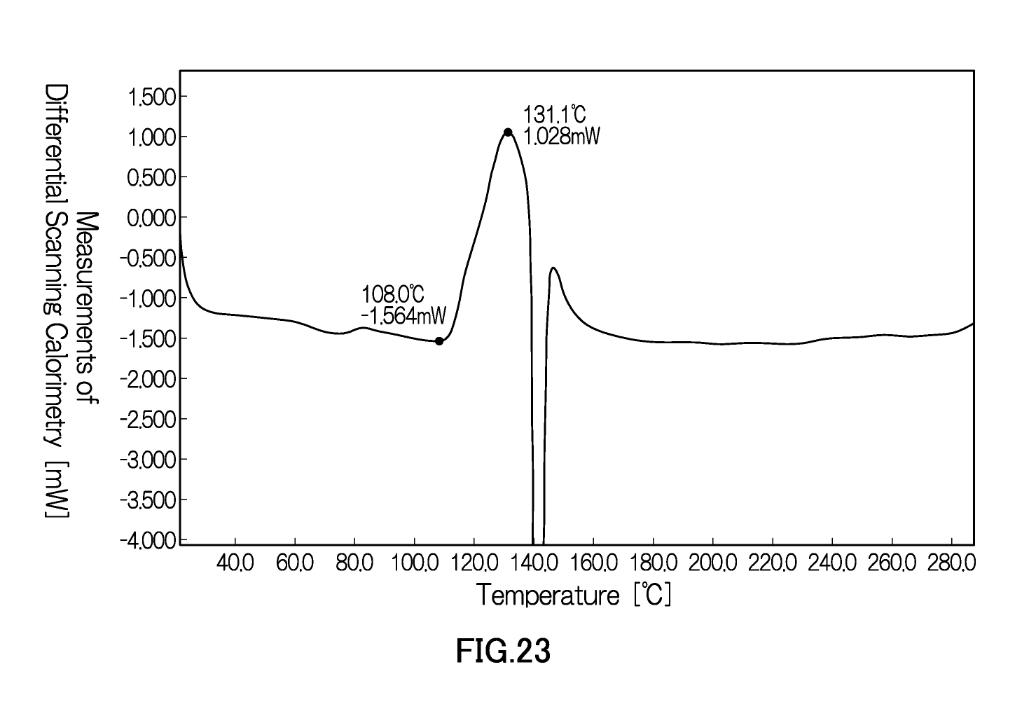

The inventors mixed the aforementioned prepared epoxy resin adhesive with the tin-bismuth powder. The proportion was set to have the epoxy resin adhesive in the amount of 15.5 weight % and the tin-bismuth powder in the amount of 84.5 weight %. The proportion was set to have tin in the amount of 43 weight % and bismuth in the amount of 57 weight % in the copper-tin alloy in the copper-tin powder. The diameter of the particles was set equal to or smaller than 10 μm (the average diameter of 3.0 μm approximately) in the tin-bismuth powder. No reaction catalyst was added. The mixture was then subjected to measurement of the differential scanning calorimetry. The temperature was raised by 10 degrees per one minute during the measurement. As depicted in FIG. 23, the peak of the exothermicity was observed at the 131.1 degrees Celsius. The temperature of 131.1 degrees Celsius was determined as the hardening reaction temperature. It has been confirmed that the hardening reaction temperature drops in response to the addition of the tin-bismuth powder.

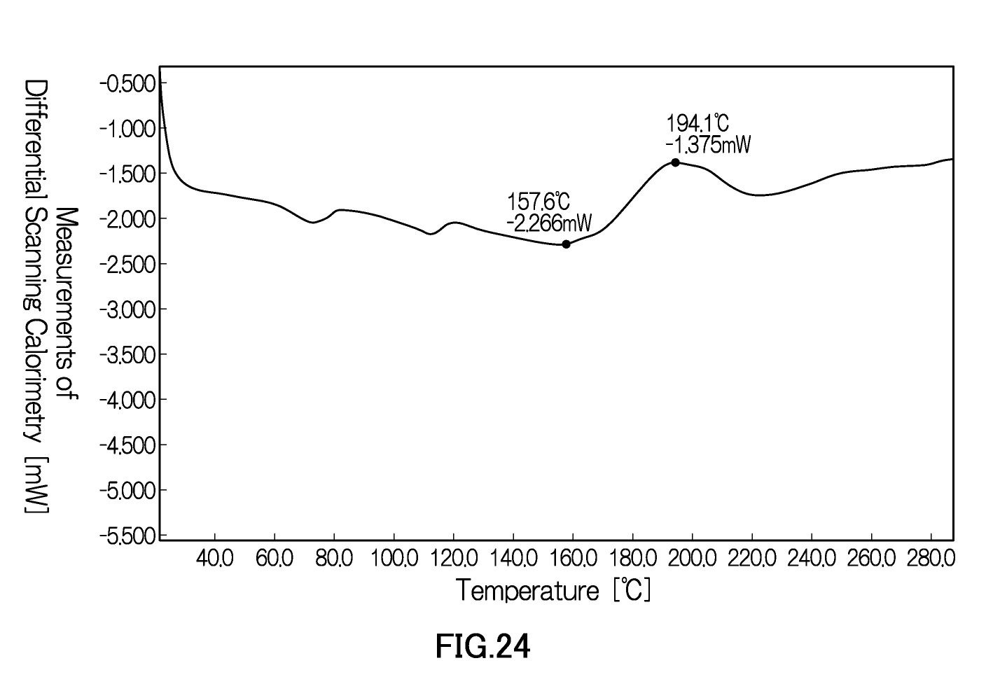

The inventors mixed the aforementioned prepared epoxy resin adhesive with silver-plated copper powder. The proportion was set to have the epoxy resin adhesive in the amount of 15.5 weight % and the silver-plated copper powder in the amount of 84.5 weight %. The surfaces of the copper particles were covered with silver plating films, respectively, having the thickness of 0.5 μm approximately in the silver-plated copper powder. The diameter of the particles was set equal to or smaller than 10 μm (the average diameter of 4.0 μm approximately) in the silver-plated copper powder. The mixture was then subjected to measurement of the differential scanning calorimetry. The temperature was raised by 10 degrees per one minute during the measurement. As depicted in FIG. 24, the peak of the exothermicity was observed at the 194.1 degrees Celsius. The temperature of 194.1 degrees Celsius was determined as the hardening reaction temperature. It has been confirmed that the hardening reaction temperature does not drop so much in response to the addition of the silver-plated copper powder as compared with the cases of the tin powder, the copper-tin powder and the tin-bismuth powder.

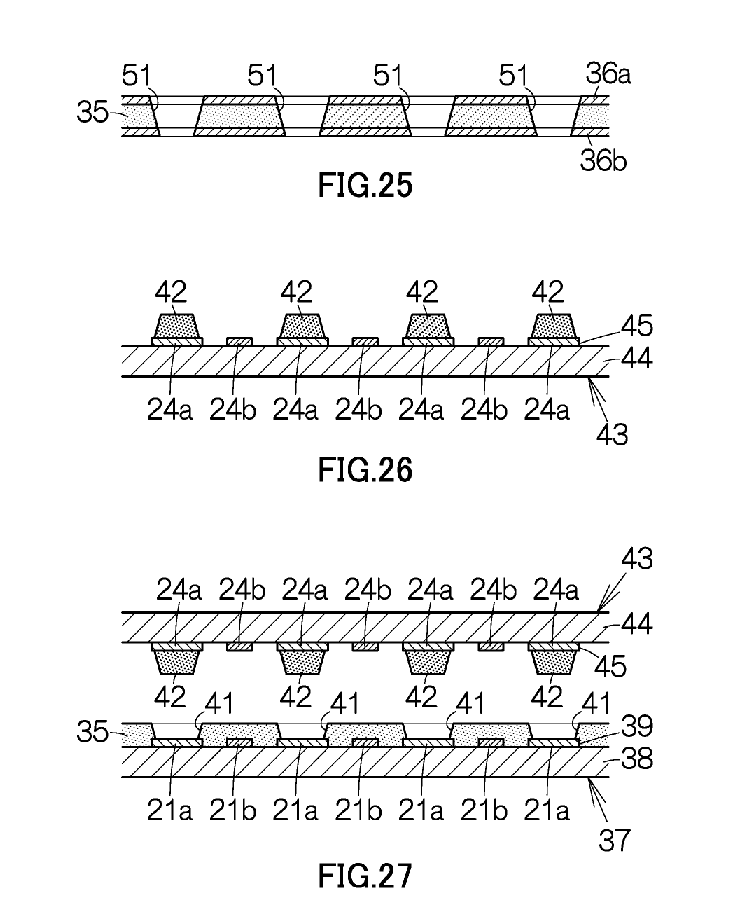

Next, a brief description will be made on a method of making the printed wiring board 12 according to a second example. The insulating resin sheet 35 is prepared in the same manner as the first example. The polyethylene terephthalate (PET) films 36a, 36b are adhered to the respective front and back surfaces of the insulating resin sheet 35. As depicted in FIG. 25, through bores 51 are formed in the insulating resin sheet 35 and the PET films 36a, 36b. Carbon dioxide gas (CO₂ gas) laser is utilized to bore the through bores 51, for example. The through bores 51 are arranged in the insulating resin sheet 35 at positions corresponding to the corresponding electrically conductive lands 21a on the first printed wiring board 37. The insulating resin sheet 35 is then overlaid on the surface of the first printed wiring board 37. The PET film 36b is peeled off from the back surface of the insulating resin sheet 35. As depicted in FIG. 5, the back surface of the insulating resin sheet 35 is thus received on the surface of the first printed wiring board 37. The back surface of the insulating resin sheet 35 is forced to cohere to the surface of the insulating layer 38. The insulating resin sheet 35 covers over the electrically conductive lands 21a and the wiring pattern 21b. The through bores 41 are formed on the corresponding electrically conductive lands 21a. The space inside the individual through bore 41 touches the corresponding electrically conductive land 21a. The subsequent processes are thereafter conducted in the aforementioned manner after the through bores 41 have been filled up with the electrically conductive paste 42. Like reference numerals are attached to the structure or component equivalent to those of the aforementioned first example.

Next, a brief description will be made on a method of making the printed wiring board 12 according to a third example. The individual through bore 41 is configured to define a space on the corresponding electrically conductive land 21a on the surface of the first printed wiring board 37 in the aforementioned manner. As depicted in FIG. 26, the electrically conductive paste 42 is then supplied to the surface of the second printed wiring board 43. Printing is employed to supply the electrically conductive paste 42, for example. Alternatively, a dispenser may be employed to supply the electrically conductive paste 42. A metal mask is, for example, overlaid on the surface of the second printed wiring board 43 for the printing of the electrically conductive paste 42. Openings are defined in the metal mask at positions corresponding to the electrically conductive lands 24a. Since the metal mask functions as a stencil plate, the electrically conductive paste 42 can be placed on the surface of the electrically conductive lands 24a. The height of the electrically conductive paste 42 may be determined based on the thickness of the metal mask. In this case, the height is measured from the surface of the electrically conductive land 24a in the direction perpendicular to the surface of the electrically conductive land 24a. The second printed wiring board 43 is thereafter overlaid on the first printed wiring board 37. As depicted in FIG. 27, the second printed wiring board 43 is reversed when the second printed wiring board 43 is overlaid. The front surface of the second printed wiring board 43 is forced to cohere to the surface of the insulating resin sheet 35. The PET film 36a is peeled off from the insulating resin sheet 35 prior to the placement of the second printed wiring board 43 on the insulating resin sheet 35. When the second printed wiring board 43 is in this manner overlaid on the surface of the insulating resin sheet 35, the through bores 41 are filled up with the electrically conductive paste 42. The opened end of the individual through bore 41 is closed with the corresponding electrically conductive land 24a. The second printed wiring board 43 is thereafter urged against the first printed wiring board 37 in the same manner as the aforementioned first example. While the second printed wiring board 43 is kept urged against the first printed wiring board 37, the first and second printed wiring boards 37, 43 are subjected to heat treatment. Like reference numerals are attached to the structure or component equivalent to those of the aforementioned first and second examples.

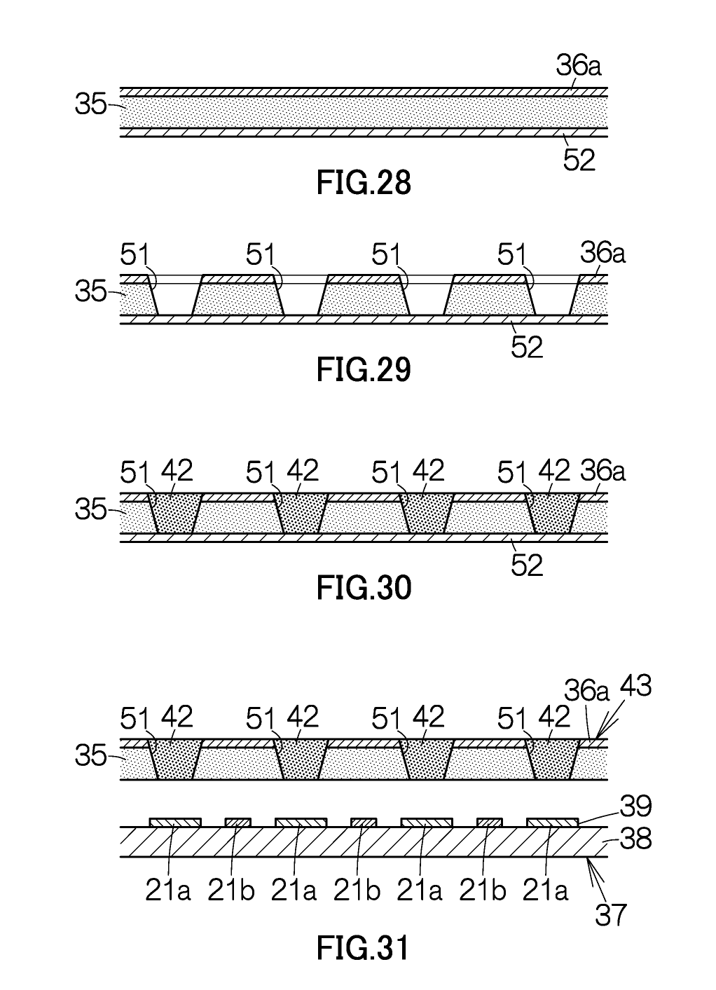

Next, a brief description will be made on a method of making the printed wiring board 12 according to a fourth example. As depicted in FIG. 28, a metal foil 52 is adhered to the back surface of the insulating resin sheet 35 in place of the PET film 36b. The metal foil 52 may be a copper foil, a nickel foil, etc., for example. The thickness of the metal foil 52 is set in range between 12 μm and 35 μm approximately. As depicted in FIG. 29, the through bores 51 are formed in the insulating resin sheet 35 and the PET film 36a. The metal foil 52 is kept during the formation of the through bores 51. As depicted in FIG. 30, the through bores 51 are then filled up with the electrically conductive paste 42. As depicted in FIG. 31, the insulating resin sheet 35 is overlaid on the surface of the first printed wiring board 37, for example, after the metal foil 52 has been peeled off. The back surface of the insulating resin sheet 35 is forced to cohere to the surface of the first printed wiring board 37. The through bores 41 are in this manner established on the respective electrically conductive lands 21a. The electrically conductive paste 42 is maintained in the through bores 41. The PET film 36a is thereafter peeled off from the surface of the insulating resin sheet 35. The second printed wiring board 43 is then overlaid on the surface of the insulating resin sheet 35 in the same manner as the first example. The subsequent processes are thereafter continued.

Next, a brief description will be made on a method of making the printed wiring board 12 according to a fifth example. The insulating resin sheet 35 is overlaid on the surface of the first printed wiring board 37 in the same manner as the aforementioned first example. The back surface of the insulating resin sheet 35 coheres to the surface of the first printed wiring board 37. The electrically conductive paste is then supplied on the electrically conductive lands 24a of the second printed wiring board 43 in the same manner as the aforementioned third example. In this case, the electrically conductive paste is made of the mixture powder including the aforementioned tin powder and the aforementioned tin-bismuth powder. An adhesive ingredient such as the resin binder is excluded from the mixture powder. The viscous agent including the activator is added to the mixture powder of the tin powder and the tin-bismuth powder. The viscous agent may be made of a material having the function similar to that of a so-called solder flux and flux vehicle. The viscous agent sublimes in response to the application of heat. Alternatively, the viscous agent is easily removed through a wash after the application of heat. Otherwise, the viscous agent may be made of an ion liquid having a reasonable viscosity and a reasonable melting point, such as imidazolium salt, pyrolidium salt, pyridinium salt, ammonium, phosphonium and sulphonium salt. Such an ion liquid allows the chloride to reduce the oxidized film of the mixture powder including the tin powder and the tin-bismuth powder. This results in a good bonding property.

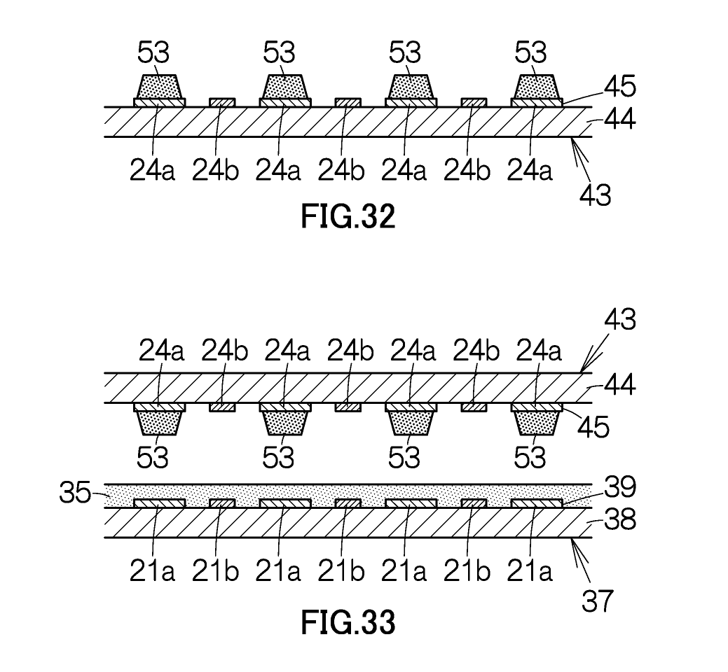

The electrically conductive paste is subjected to heat treatment. The heat treatment under the nitrogen atmosphere enables prevention of oxidation of the metallic powder in the electrically conductive paste. When the temperature exceeds the eutectic temperature of tin-bismuth alloy, the tin-bismuth powder melts in the electrically conductive paste in the aforementioned manner. The melt of the tin-bismuth powder induces the melt of the tin particles. Tin and copper are incompletely integrated into mass. The electrically conductive paste gets solidified on the electrically conductive lands 24a. As depicted in FIG. 32, solid protrusions 53 are formed on the individual electrically conductive lands 24a. The second printed wiring board 43 is washed after the heat treatment. Organic solvent or hydrocarbon based solvent is employed to wash the second printed wiring board 43. The hydrocarbon based solvent includes a so-called flux washing agent. The solvent serves to remove the chlorides adhering to the surface of the second printed wiring board 43.

As depicted in FIG. 33, the second printed wiring board 43 is overlaid on the first printed wiring board 37. The second printed wiring board 43 is reversed when the second printed wiring board 43 is overlaid. The front surface of the second printed wiring board 43 is forced to cohere to the surface of the insulating resin sheet 35. The PET film 36a is peeled off from the insulating resin sheet 35 prior to the placement of the second printed wiring board 43 on the insulating resin sheet 35. The insulating resin sheet 35 gets softened. When the second printed wiring board 43 is urged against the surface of the first printed wiring board 37, the solid protrusions 53 are forced to dig into the insulating resin sheet 35. The tip ends of the solid protrusions 53 are allowed to touch the respective electrically conductive lands 21a on the first printed wiring board 37. When the temperature exceeds the eutectic temperature of tin-bismuth alloy, the remaining tin-bismuth phases melts. The tin powder thus completely gets solidified. The solid protrusions 53 form the diffusion layers 32 on the respective electrically conductive lands 21a, 24a. Tin and copper form the tin-copper based intermetallic compounds, namely Cu₆Sn₅ in the aforementioned manner.

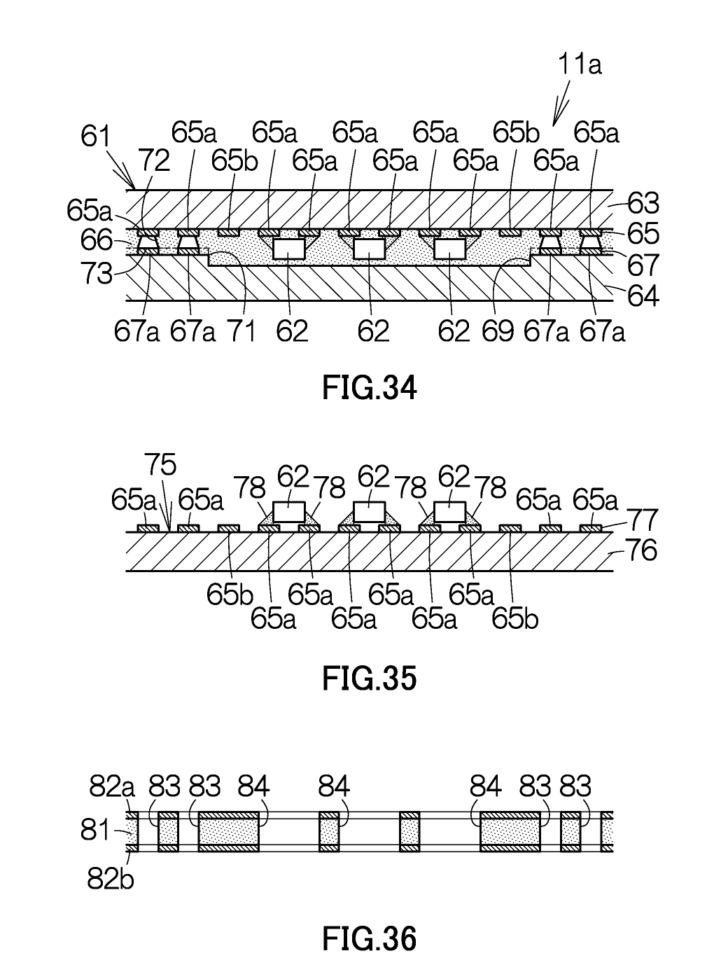

FIG. 34 schematically illustrates a printed circuit board unit according to a second embodiment. The printed circuit board unit 11a includes a printed wiring board 61. One or more electronic components 62 are embedded in the printed wiring board 61. The electronic components 62 may be, for example, a passive element such as a resistor chip and/or an active element such as an LSI chip.

The printed wiring board 61 includes a first insulating layer 63 and a second insulating layer 64. The first and second insulating layers 63, 64 have an electrical insulation. The first and second insulating layers 63, 64 are made of thermosetting resin such as epoxy resin, for example, in the same manner as the aforementioned first and second insulating layers 18, 19. Glass fiber cloth is, for example, likewise embedded in the first and second insulating layers 63, 64.

The first electrically conductive layer 65 as a first electrically conductive material is formed on the surface of the first insulating layer 63. The first electrically conductive layer 65 includes one or more electrically conductive lands 65a and a wiring pattern 65b. The electrically conductive lands 65a serve as an electrically conductive layer. The electrically conductive lands 65a and the wiring pattern 65b have the structure similar to that of the aforementioned electrically conductive lands 21a and wiring pattern 21b. The wiring pattern 65b connects the electrically conductive lands 65a to one another, for example. The wiring pattern 65b serves to establish various signal paths. The electronic components 62 are soldered to the respective electrically conductive lands 65a, for example. The electronic components 62 are electrically connected to the first electrically conductive layer 65. Alternatively, the electronic components 62 may be adhered to the respective electrically conductive lands 65a with an electrically conductive adhesive.

An intermediate insulating layer 66 is overlaid on the surface of the first electrically conductive layer 65. The intermediate insulating layer 66 has an electrical insulation. The intermediate insulating layer 66 is made of thermosetting resin such as epoxy resin, for example. The back surface of the intermediate insulating layer 66 uniformly coheres to the surface of the first insulating layer 63. The intermediate insulating layer 66 covers over the first electrically conductive layer 65.

The intermediate insulating layer 66 is overlaid on the surface of a second electrically conductive layer 67 serving as a second electrically conductive material. The second electrically conductive layer 67 includes one or more electrically conductive lands 67a and a wiring pattern, not depicted. The electrically conductive lands 67a serve as an electrically conductive layer. The electrically conductive lands 67a and the wiring pattern have the structure similar to that of the aforementioned electrically conductive lands 24a and wiring pattern 24b. The wiring pattern connects the electrically conductive lands 67a to one another, for example. The wiring pattern serves to establish various signal paths.

The second electrically conductive layer 67 is overlaid on the surface of the second insulating layer 64. The intermediate insulating layer 66 uniformly coheres to the surface of the second insulating layer 64. The intermediate insulating layer 66 covers over the second electrically conductive layer 67. A depression or depressions 69 is formed on the surface of the second insulating layer 64. A void or voids 71 is formed in the second electrically conductive layer 67. The void 71 have the same contour as the depression 69. The void 71 and the depression 69 are filled up with the intermediate insulating layer 66. The electronic components 62 are placed in a space defined inside the void 71 and the depression 69.

A through bore or through bores 72 are formed in the intermediate insulating layer 66 so as to penetrate through the intermediate insulating layer 66 between the back surface thereof and the front surface thereof. The individual through bore 72 defines a space touching the electrically conductive land 65a and the corresponding electrically conductive land 67a. The space has a columnar shape having the central axis perpendicular to the flat surfaces of the electrically conductive lands 65a, 67a, for example. The space is filled up with an electrically conductive bonding material 73. The bonding material 73 has the same composition as the aforementioned bonding material 25. The bonding material 73 connects the electrically conductive lands 65a of the first electrically conductive layer 65 to the corresponding electrically conductive lands 67a of the second electrically conductive layer 67, respectively, for electric conduction. So-called vias are thus formed. Electric connection is established. Electric signals are transmitted between the electrically conductive lands 65a and the corresponding electrically conductive lands 67a. Various signal paths are in this manner established on the printed wiring board 61. Electric signals are transmitted between the electronic components 62 as well as between the electronic components 62 and other electronic component or components on the printed wiring board 61.

Next, description will be made on a method of making the printed wiring board 61 according to a specific example. First of all, a first printed wiring board 75 is prepared, as depicted in FIG. 35. The first printed wiring board 75 includes an insulating layer 76 and an electrically conductive layer 77. The insulating layer 76 corresponds to the aforementioned first insulating layer 63. The electrically conductive layer 77 corresponds to the aforementioned first electrically conductive layer 65. The electrically conductive layer 77 is formed on the surface of the insulating layer 76. A copper foil is, for example, cohered to the surface of the insulating layer 76 so as to form the electrically conductive layer 77. Photolithography technique is, for example, employed to form or shape the electrically conductive lands 65a and the wiring pattern 65b out of the copper foil.

The electronic components 62 are mounted on the first printed wiring board 75. Solder 78 is employed to mount the electronic components 62, for example. The solder 78 serves to bond the electrodes of the electronic components 62 to the corresponding electrically conductive lands 65a.

As depicted in FIG. 36, an insulating resin sheet 81 is prepared. Polyethylene terephthalate (PET) films 82a, 82b are adhered to the respective front and back surfaces of the insulating resin sheet 81. The insulating resin sheet 81 and the PET films 82a, 82b have the same structure as the aforementioned insulating resin sheet 35 and the PET films 36a, 36b. Through bores 83 are formed in the insulating resin sheet 81 and the PET films 82a, 82b. Carbon dioxide gas (CO₂ gas) laser is utilized to bore the through bores 83, for example, in the aforementioned manner. The through bores 83 are arranged in the insulating resin sheet 83 and the PET films 82a, 82b at positions corresponding to the corresponding electrically conductive lands 65a on the first printed wiring board 75. Openings 84 are likewise formed in the insulating resin sheet 81 and the PET films 82a, 82b. The openings 84 are arranged in the insulating resin sheet 81 and the PET films 82a, 82b at positions corresponding to the corresponding electronic components 62 on the first printed wiring board 75.

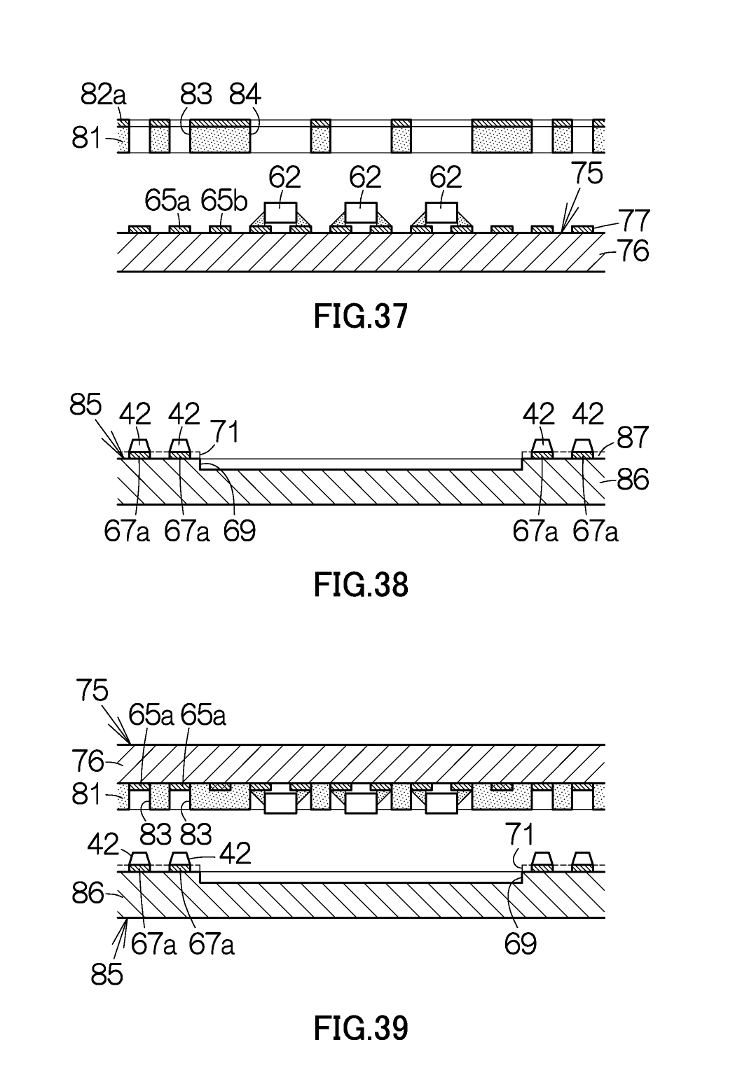

As depicted in FIG. 37, the insulating resin sheet 81 is overlaid on the surface of the first printed wiring board 75. The PET film 82b is peeled off from the back surface of the insulating resin sheet 81. The back surface of the insulating resin sheet 81 is thus received on the surface of the first printed wiring board 75. The back surface of the insulating resin sheet 81 is forced to cohere to the surface of the insulating layer 76. The insulating resin sheet 81 covers over the electrically conductive lands 65a and the wiring pattern 65b. The through bores 83 are formed on the corresponding electrically conductive lands 65a. The space inside the individual through bore 83 touches the corresponding electrically conductive land 65a. The electronic components 62 are thus placed within the corresponding openings 84.

As depicted in FIG. 38, a second printed wiring board 85 is prepared. The second printed wiring board 85 includes an insulating layer 86 and an electrically conductive layer 87. The insulating layer 86 corresponds to the aforementioned second insulating layer 64. The electrically conductive layer 87 corresponds to the aforementioned second electrically conductive layer 67. The electrically conductive layer 87 is formed on the surface of the insulating layer 86. A copper foil is, for example, cohered to the surface of the insulating layer 86 so as to form the electrically conductive layer 87. Photolithography technique is, for example, employed to form or shape the electrically conductive lands 67a and the wiring pattern, not depicted, out of the copper foil. The depression or depressions 69 is formed on the surface of the insulating layer 86. The void or voids 71 are formed in the electrically conducive layer 87 so as to have the contour matched with that of the depression 69.

As depicted in FIG. 38, the electrically conductive paste 42 is then supplied to the surface of the second printed wiring board 85. The electrically conductive paste 42 may be printed on the surface of the second printed wiring board 85 in the aforementioned manner, for example. Alternatively, a dispenser may be utilized to supply the electrically conductive paste 42. A metal mask is, for example, overlaid on the surface of the second printed wiring board 85 for the printing of the electrically conductive paste 42. Openings are defined in the metal mask at positions corresponding to the electrically conductive lands 67a. Since the metal mask functions as a stencil plate, the electrically conductive paste 42 can be placed on the surface of the electrically conductive lands 67a. The height of the electrically conductive paste 42 may be determined based on the thickness of the metal mask. In this case, the height is measured from the surface of the electrically conductive land 67a in the direction perpendicular to the surface of the electrically conductive land 67a.

As depicted in FIG. 39, the first printed wiring board 75 is overlaid on the second printed wiring board 85. The first printed wiring board 75 is reversed when the first printed wiring board 75 is overlaid. The front surface of the insulating resin sheet 81 is forced to cohere to the surface of the second printed wiring board 85. The PET film 82a is peeled off from the insulating resin sheet 81 prior to the placement of the insulating resin sheet 81 on the second printed wiring board 85. When the insulating resin sheet 81 is in this manner overlaid on the surface of the second printed wiring board 85, the through bores 83 are filled up with the electrically conductive paste 42. The opened end of the individual through bore 83 is closed with the corresponding electrically conductive land 67a. The depression 69 and the void 71 are also filled with the material of the insulating resin sheet 81. The first printed wiring board 75 is thereafter urged against the second printed wiring board 85 in the aforementioned manner. While the first printed wiring board 75 is kept urged against the second printed wiring board 85, the first and second printed wiring boards 75, 85 are subjected to heat treatment. Like reference numerals are attached to the structure or component equivalent to those of the aforementioned first and second examples.

It should be noted that the individual process or a group of the processes in the method of making the printed wiring board 61 can be replaced with any various processes in the same manner as the method of making the printed wiring board 12. The method of making the printed wiring board 12, 61 is not limited to the disclosed processes.

All examples and conditional language recited herein are intended for pedagogical purposes to aid the reader in understanding the invention and the concept contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. An electrically conductive body comprising:
a first electrically conductive material;
a second electrically conductive material; and
a bonding material bonding the first electrically conductive material to the second electrically conductive material at least for electric conduction, the bonding material being made of a metallic structure containing copper-tin based intermetallic compound phases and tin-bismuth phases, the copper-tin based intermetallic compound phases being continuous between the first electrically conductive material and the second electrically conductive material, the tin-bismuth phases being surrounded by the copper-tin based intermetallic compound phases.

2. The electrically-conductive body according to claim 1, wherein the tin-bismuth phases are contained in the bonding material at a content enough to avoid melting reaction of the bonding material at a temperature lower than a temperature related to an eutectic temperature intrinsic to tin-bismuth alloy.

3. The electrically conductive body according to claim 2, wherein the copper-tin based intermetallic compound phases are made of Cu₆Sn₅.

4. A printed wiring board comprising:
a first insulating layer;
a first electrically conductive layer formed on a surface of the first insulating layer;
an intermediate insulating layer having a back surface overlaid on the first electrically conductive layer, the intermediate insulating layer defining a through bore penetrating through the intermediate insulating layer between the back surface and a front surface opposite to the back surface, a space inside the through bore touching at least partly a surface of the first electrically conductive layer;
a second electrically conductive layer overlaid on the intermediate insulating layer, the second electrically conductive layer touching at least partly the space inside the through bore;
a second insulating layer overlaid on the second electrically conductive layer; and
a bonding material filling up the space inside the through bore, the bonding material bonding the first electrically conductive layer to the second electrically conductive layer at least for electric conduction, the bonding material being made of a metallic structure containing copper-tin based intermetallic compound phases and tin-bismuth phases, the copper-tin based intermetallic compound phases being continuous between the first electrically conductive layer and the second electrically conductive layer, the tin-bismuth phases being surrounded by the copper-tin based intermetallic compound phases.

5. The printed wiring board according to claim 4, wherein the tin-bismuth phases are contained in the bonding material at a content enough to avoid melting reaction of the bonding material at a temperature lower than a temperature related to an eutectic temperature intrinsic to tin-bismuth alloy.

6. The printed wiring board according to claim 5, wherein the copper-tin based intermetallic compound phases are made of Cu₆Sn₅.

7. A method of making an electrically conductive body, the method comprising:
filling up a space between a first electrically conductive material and a second electrically conductive material with electrically conductive paste containing tin powder and tin-bismuth powder, the tin powder comprising tin particles containing a supersaturated solid solution of copper; and
heating the electrically conductive paste at a temperature equal to or higher than a eutectic temperature of tin-bismuth alloy and lower than a solidus temperature of copper-tin alloy, thereby forming copper-tin based intermetallic compound phases continuous between the first electrically conductive material and the second electrically conductive material.

8. The method according to claim 7, wherein the copper-tin based intermetallic compound phases are made of Cu₆Sn₅.

9. The method according to claim 7, wherein the tin powder includes tin ingredient and copper ingredient at a proportion to set a eutectic temperature of copper-tin alloy at 227 degrees Celsius.

10. A method of making a printed wiring board, the method comprising:
applying electrically conductive paste to a surface of an electrically conductive layer, the electrically conductive paste containing tin powder and tin-bismuth powder, the tin powder comprising tin particles containing a supersaturated solid solution of copper; and
heating the electrically conductive paste at a temperature equal to or higher than a eutectic temperature of tin-bismuth alloy and lower than a solidus temperature of copper-tin alloy, thereby forming copper-tin based intermetallic compound phases continuous to stand from the electrically conductive layer.

11. A method of making a printed wiring board, the method comprising:
forming a space in a second insulating layer overlaid on a surface of a first insulating layer, the space erect on a surface of a first electrically conductive layer formed on the surface of the first insulating layer, the space being open at a surface of the second insulating layer, the space filled up with electrically conductive paste containing tin powder and tin-bismuth powder, the tin powder comprising tin particles containing a supersaturated solid solution of copper;
placing a surface of a third insulating layer against the surface of the second insulating layer, thereby closing an opened end of the space with a second electrically conductive layer formed on the surface of the third insulating layer; and
heating the electrically conductive paste at a temperature equal to or higher than a eutectic temperature of tin-bismuth alloy and lower than a solidus temperature of copper-tin alloy, thereby forming copper-tin based intermetallic compound phases continuous between the first electrically conductive layer and the second electrically conductive layer.

12. The method according to claim 11, wherein the copper-tin based intermetallic compound phases are made of Cu₆Sn₅.

13. The method according to claim 11, wherein the tin powder includes tin ingredient and copper ingredient at a proportion to set a eutectic temperature of copper-tin alloy at 227 degrees Celsius.

14. The method according to claim 13, wherein the tin-bismuth powder includes tin ingredient and bismuth ingredient at a proportion to set a solidus temperature at a temperature lower than glass transition temperatures of the first insulating layer, the second insulating layer and the third insulating layer.

15. The method according to claim 14, wherein the electrically conductive paste contains the tin-bismuth powder at a proportion equal to or smaller than 20 weight percent to a total amount of the tin powder and the tin-bismuth powder.

16. A method of making a printed wiring board, the method comprising:
forming a space in a second insulating layer overlaid on a surface of a first insulating layer, the space erect on a surface of a first electrically conductive layer formed on the surface of the first insulating layer, the space being open at a surface of the second insulating layer;
placing a surface of a third insulating layer against the surface of the second insulating layer, thereby closing an opened end of the space with a second electrically conductive layer formed on the surface of the third insulating layer, while filling the space up with electrically conductive paste containing tin powder and tin-bismuth powder, the tin powder comprising tin particles containing a supersaturated solid solution of copper; and
heating the electrically conductive paste at a temperature equal to or higher than a eutectic temperature of tin-bismuth alloy and lower than a solidus temperature of copper-tin alloy, thereby forming copper-tin based intermetallic compound phases continuous between the first electrically conductive layer and the second electrically conductive layer.

17. The method according to claim 16, wherein the copper-tin based intermetallic compound phases are made of Cu₆Sn₅.

18. The method according to claim 16, wherein the tin powder includes tin ingredient and copper ingredient at a proportion to set a eutectic temperature of copper-tin alloy at 227 degrees Celsius.

19. The method according to claim 18, wherein the tin-bismuth powder includes tin ingredient and bismuth ingredient at a proportion to set a solidus temperature at a temperature lower than glass transition temperatures of the first insulating layer, the second insulating layer and the third insulating layer.

20. The method according to claim 19, wherein the electrically conductive paste contains the tin-bismuth powder at a proportion equal to or smaller than 20 weight percent to a total amount of the tin powder and the tin-bismuth powder.

21. Electrically conductive paste containing tin powder and tin-bismuth powder, the tin powder comprising tin particles containing a supersaturated solid solution of copper, the electrically conductive paste configured to form copper-tin based intermetallic compound phases continuous at least in a predetermined direction when heated at a temperature equal to or higher than a eutectic temperature of tin-bismuth alloy and lower than a solidus temperature of copper-tin alloy.

22. The electrically conductive paste according to claim 21, wherein the copper-tin based intermetallic compound phases are made of Cu₆Sn₅.

23. The electrically conductive paste according to claim 21, wherein the tin powder includes tin ingredient and copper ingredient at a proportion to set a eutectic temperature of copper-tin alloy at 227 degrees Celsius.
